(19) United States
(12) Patent Application Publication
(10) Pub. No.: US 2026/0206345 A1
(43) Pub. Date: Jul. 16, 2026

(54) IMAGING ELEMENT, MANUFACTURING METHOD OF IMAGING ELEMENT, AND ELECTRONIC EQUIPMENT

(71) Applicant: Sony Semiconductor Solutions Corporation, Kanagawa (JP)

(72) Inventors: Yilun He, Tokyo (JP); Shigehiro Ikehara, Kanagawa (JP)

(21) Appl. No.: 19/134,070

(22) PCT Filed: Nov. 8, 2023
(86) PCT No.: PCT/JP23/40161

§ 371 Date: May 29, 2025

(30) Foreign Application Priority Data
Dec. 16, 2022 (JP) 2022-201551

(51) Int. Cl. H10F 39/00; H10F 39/18

(52) U.S. Cl. CPC H10F 39/8057; H10F 39/014; H10F 39/024; H10F 39/182; H10F 39/80373

(57) ABSTRACT

Imaging elements with suppressed noise generation are disclosed. In one example, an imaging element includes a semiconductor substrate, a photoelectric conversion section, a charge holding section MEM, a first light shielding section, and a second light shielding section. The light shielding sections include vertical light shielding sections and horizontal light shielding sections with a hexagonal shape when viewed from a direction orthogonal to a first surface of the substrate. The horizontal light shielding section of the second light shielding section is disposed closer to the second surface than the horizontal light shielding section of the first light shielding section, and is disposed to cover at least a part of a region where the horizontal light shielding section of the first light shielding section is not disposed.

### TECHNICAL FIELD

The present disclosure relates to an imaging element that performs imaging by photoelectric conversion, a manufacturing method of the imaging element, and electronic equipment.

### BACKGROUND ART

A global shutter imaging element that images all pixels at the same timing is known. In this type of imaging element, each pixel is provided with a charge holding section that accumulates a charge generated by a photoelectric conversion section. In such an imaging element, a technique has been proposed in which the photoelectric conversion section and the charge holding section are stacked, and a light shielding section is formed between the photoelectric conversion section and the charge holding section, thereby preventing noise of a charge due to light that has not been absorbed by the photoelectric conversion section and has passed while securing an area of the charge holding section (See, for example, Patent Documents 1 and 2).

### CITATION LIST

### Patent Document

Patent Document 1: WO 2021/111818 A
Patent Document 2: WO 2022/102509 A

### SUMMARY OF THE INVENTION

### Problems to be Solved by the Invention

An object of the present disclosure is to provide an imaging element in which generation of noise is suppressed.

### Solutions to Problems

An imaging element according to one aspect of the present disclosure includes: a semiconductor substrate including a first surface and a second surface opposed to the first surface; and a photoelectric conversion section, a charge holding section, a first light shielding section, and a second light shielding section disposed in the semiconductor substrate, in which each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface, the photoelectric conversion section is disposed closer to the second surface than the horizontal light shielding section of the first light shielding section, the charge holding section is disposed closer to the first surface than the horizontal light shielding section of the first light shielding section, and the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface. The horizontal light shielding section of the second light shielding section may be further disposed to cover at least a part of a region where the horizontal light shielding section of the first light shielding section is disposed. The horizontal light shielding section of the second light shielding section may be disposed to cover all of a region where the horizontal light shielding section of the first light shielding section is not disposed when viewed from the direction orthogonal to the first surface.

The imaging element may further include a vertical gate electrode disposed in the semiconductor substrate and extending in the direction orthogonal to the first surface, and the vertical gate electrode may be disposed closer to the first surface than the horizontal light shielding section of the first light shielding section.

In the imaging element, the semiconductor substrate may include a single-crystal silicon substrate in which the first plane includes a crystal plane with a plane index {111}, the vertical light shielding section may include a portion extending in a first direction and a portion extending in a second direction non-parallel to the first direction when viewed from the direction orthogonal to the first plane, and all of six sides of the hexagonal shape of the horizontal light shielding section may have at least one intersection with the vertical light shielding section. The first direction may be a crystal direction with a direction index <112>, and the second direction may be a crystal direction with a direction index <110>.

The imaging element may further include a pinning layer disposed in a region around the first light shielding section and the second light shielding section in the semiconductor substrate and formed as a P type semiconductor region.

In the imaging element, the vertical light shielding section of each of the first light shielding section and the second light shielding section may extend from at least the first surface to the horizontal light shielding section. In the imaging element, the vertical light shielding section of each of the first light shielding section and the second light shielding section may penetrate the semiconductor substrate.

A manufacturing method of an imaging element according to one aspect of the present disclosure includes: a photoelectric conversion section forming step of forming a photoelectric conversion section in a semiconductor substrate including a first surface and a second surface opposite to the first surface; a charge holding section forming step of forming a charge holding section in the semiconductor substrate; and a light shielding section forming step of forming a first light shielding section and a second light shielding section in the semiconductor substrate, in which each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface, the photoelectric conversion section is disposed closer to the second surface than the horizontal light shielding section of the first light shielding section, the charge holding section is disposed closer to the first surface than the horizontal light shielding section of the first light shielding section, and the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.

In the manufacturing method of an imaging element, a single-crystal silicon substrate in which the first surface is a crystal plane with a plane index {111} may be used as the semiconductor substrate, and the light shielding section forming step may include: a trench forming step of forming a trench that spreads in a wall shape from the first surface in a direction orthogonal to the first surface; and a horizontal cavity portion forming step of forming a horizontal cavity portion that spreads in a plate shape in a direction parallel to the first surface by crystal anisotropic wet etching from the trench formed in the trench forming step and has a hexagonal shape when viewed from the direction orthogonal to the first surface. The light shielding section forming step may include a step of forming a pinning layer in a region around the trench and the horizontal cavity portion in the semiconductor substrate by diffusing P type impurities from the trench formed in the trench forming step and an inner surface of the horizontal cavity portion formed in the horizontal cavity portion forming step.

Electronic equipment according to one aspect of the present disclosure is electronic equipment including the imaging element.

### BRIEF DESCRIPTION OF DRAWINGS

FIG. 1 is a block diagram illustrating a schematic configuration of an imaging element according to the present embodiment.

FIG. 2 is an equivalent circuit diagram of a sensor pixel.

FIG. 3 is a planar layout diagram illustrating some pixel regions in a pixel array section.

FIG. 4 is a planar layout diagram illustrating a pixel region for one pixel, and illustrates a region A in FIG. 3.

FIG. 5 is a longitudinal cross-sectional view illustrating a cross-sectional structure of the imaging element, and illustrates a cross section taken along line B-B in FIG. 3.

FIG. 6 is a longitudinal cross-sectional view illustrating a cross-sectional structure of the imaging element, and illustrates a cross section taken along line C-C in FIG. 3.

FIG. 7 is a longitudinal cross-sectional view illustrating details of a cross-sectional structure of the imaging element, and illustrates a region D in FIG. 5.

FIG. 8 is a transverse cross-sectional view illustrating an arrangement of a first light shielding section, and illustrates a cross section taken along line E-E in FIG. 5.

FIG. 9 is a transverse cross-sectional view illustrating an arrangement of a second light shielding section, and illustrates a cross section taken along line F-F in FIG. 5.

FIG. 10 is a longitudinal cross-sectional view illustrating a positional relationship between a horizontal light shielding section of each of the first light shielding section and the second light shielding section and a light condensing center of the imaging element.

FIG. 11 is a transverse cross-sectional view illustrating a positional relationship between a horizontal light shielding section of each of the first light shielding section and the second light shielding section and the light condensing center of the imaging element, and illustrates a cross section taken along line G-G in FIG. 10.

FIG. 12A is a longitudinal cross-sectional view illustrating an example of a manufacturing method of the imaging element according to the present embodiment.

FIG. 12B is a longitudinal cross-sectional view continuing from FIG. 12A.

FIG. 12C is a longitudinal cross-sectional view continuing from FIG. 12B.

FIG. 12D is a longitudinal cross-sectional view continuing from FIG. 12C.

FIG. 12E is a longitudinal cross-sectional view continuing from FIG. 12D.

FIG. 12F is a longitudinal cross-sectional view continuing from FIG. 12E.

FIG. 12G is a longitudinal cross-sectional view continuing from FIG. 12F.

FIG. 12H is a longitudinal cross-sectional view continuing from FIG. 12G.

FIG. 12I is a longitudinal cross-sectional view continuing from FIG. 12H.

FIG. 12J is a longitudinal cross-sectional view continuing from FIG. 12I.

FIG. 12K is a longitudinal cross-sectional view continuing from FIG. 12J.

FIG. 12L is a longitudinal cross-sectional view continuing from FIG. 12K.

FIG. 12M is a longitudinal cross-sectional view continuing from FIG. 12L.

FIG. 12N is a longitudinal cross-sectional view continuing from FIG. 12M.

FIG. 13A is a transverse cross-sectional view illustrating a process of forming a horizontal cavity portion by anisotropic wet etching.

FIG. 13B is a longitudinal cross-sectional view illustrating a process of forming the horizontal cavity portion by anisotropic wet etching, and illustrates an H-H cross section of FIG. 13A.

FIG. 14A is a plan view for explaining a relationship between an arrangement of trenches and a shape of horizontal cavity portions formed by the arrangement of the trenches.

FIG. 14B is a plan view for explaining the relationship between the arrangement of trenches and the shape of horizontal cavity portions formed by the arrangement of the trenches.

FIG. 15A is a plan view illustrating a modification of the configuration of a vertical light shielding section and the horizontal light shielding section.

FIG. 15B is a plan view illustrating a modification of the configuration of the vertical light shielding section and the horizontal light shielding section.

FIG. 15C is a plan view illustrating a modification of the configuration of the vertical light shielding section and the horizontal light shielding section.

FIG. 15D is a plan view illustrating a modification of the configuration of the vertical light shielding section and the horizontal light shielding section.

FIG. 15E is a plan view illustrating a modification of the configuration of the vertical light shielding section and the horizontal light shielding section.

FIG. 15F is a plan view illustrating a modification of the configuration of the vertical light shielding section and the horizontal light shielding section.

FIG. 16A is a longitudinal cross-sectional view illustrating a modification of the arrangement of the vertical light shielding section.

FIG. 16B is a longitudinal cross-sectional view illustrating a modification of the arrangement of the vertical light shielding section.

FIG. 16C is a longitudinal cross-sectional view illustrating a modification of the arrangement of the vertical light shielding section.

FIG. 16D is a longitudinal cross-sectional view illustrating a modification of the arrangement of the vertical light shielding section.

FIG. 16E is a longitudinal cross-sectional view illustrating a modification of the arrangement of the vertical light shielding section.

FIG. 16F is a longitudinal cross-sectional view illustrating a modification of the arrangement of the vertical light shielding section.

FIG. 16G is a longitudinal cross-sectional view illustrating a modification of the arrangement of the vertical light shielding section.

FIG. 16H is a longitudinal cross-sectional view illustrating a modification of the arrangement of the vertical light shielding section.

FIG. 17 is a longitudinal cross-sectional view illustrating a modification of the number of stages of the horizontal light shielding section.

FIG. 18A is a longitudinal cross-sectional view illustrating a modification of a vertical gate electrode VG.

FIG. 18B is a longitudinal cross-sectional view illustrating a modification of the vertical gate electrode VG.

FIG. 18C is a longitudinal sectional view illustrating a modification of the vertical gate electrode VG.

FIG. 19A is a longitudinal cross-sectional view illustrating a modification of light shielding material portions of the first light shielding section and the second light shielding section.

FIG. 19B is a longitudinal cross-sectional view illustrating a modification of the light shielding material portions of the first light shielding section and the second light shielding section.

FIG. 19C is a longitudinal cross-sectional view illustrating a modification of the light shielding material portions of the first light shielding section and the second light shielding section.

FIG. 20A is a transverse cross-sectional view for explaining a modification of a longitudinal cross-sectional shape of the horizontal light shielding section.

FIG. 20B is a longitudinal cross-sectional view illustrating a modification of a longitudinal sectional shape of the horizontal light shielding section, and illustrates a cross section taken along line I-I in FIG. 20A.

FIG. 20C is a longitudinal cross-sectional view illustrating a modification of a longitudinal sectional shape of the horizontal light shielding section, and illustrates a cross section taken along line I-I in FIG. 20A.

FIG. 20D is a longitudinal cross-sectional view illustrating a modification of a longitudinal sectional shape of the horizontal light shielding section, and illustrates a cross section taken along line I-I in FIG. 20A.

FIG. 20E is a longitudinal cross-sectional view illustrating a modification of a longitudinal sectional shape of the horizontal light shielding section, and illustrates a cross section taken along line I-I in FIG. 20A.

FIG. 20F is a longitudinal cross-sectional view illustrating a modification of a longitudinal sectional shape of the horizontal light shielding section, and illustrates a cross section taken along line I-I in FIG. 20A.

FIG. 20G is a longitudinal cross-sectional view illustrating a modification of a longitudinal sectional shape of the horizontal light shielding section, and illustrates a cross section taken along line I-I in FIG. 20A.

FIG. 21A is a longitudinal cross-sectional view illustrating a modification of a layer configuration in a semiconductor substrate of the imaging element.

FIG. 21B is a longitudinal cross-sectional view illustrating a modification of a layer configuration in the semiconductor substrate of the imaging element.

FIG. 22 is a block diagram illustrating a configuration example of a camera as electronic equipment.

FIG. 23 is a block diagram illustrating a schematic configuration example of a vehicle control system as an example of a mobile body control system.

FIG. 24 is a diagram illustrating an example of the installation positions of the imaging sections.

### MODE FOR CARRYING OUT THE INVENTION

Below, an example of an embodiment of the present disclosure (hereinafter referred to as the present embodiment) will be described with reference to the drawings. Note that the description is given in the following order.
1. Structure of imaging element of present embodiment
2. Manufacturing method of imaging element of present embodiment
3. Modifications
4. Example of application to electronic equipment
5. Example of application to mobile body
6. Summary

### 1. Structure of Imaging Element of Present Embodiment

An imaging element 101 of the present embodiment is a global shutter back-illuminated image sensor such as a complementary metal oxide semiconductor (CMOS) image sensor. The imaging element 101 of the present embodiment receives light from a subject for each pixel, photoelectrically converts the light, and generates a pixel signal that is an electric signal.

The global shutter method is a method of simultaneously starting and ending exposure of all pixels. Here, “all pixels” means all the pixels that form an effective image, and dummy pixels and the like that do not contribute to image formation are excluded. Furthermore, if image distortion and the exposure time difference are sufficiently small so as not to cause any problem, the exposure does not necessarily have to be simultaneous. For example, the global shutter method also includes a case where an operation of performing simultaneous exposure in units of a plurality of rows (such as several tens of rows) is repeated while being shifted in units of a plurality of rows in a row direction. Furthermore, the global shutter method also includes a case where simultaneous exposure is performed only for some pixel regions.

A back-illuminated image sensor is an image sensor in which a photoelectric conversion section such as a photodiode that receives light from the subject and converts the light into an electrical signal is provided for each pixel between a light receiving surface on which the light from the subject is incident and a wiring layer including wiring lines of a transistor or the like that drives each pixel. Note that a technology according to the present disclosure can be applied to an image sensor of an imaging system other than a CMOS image sensor in some cases.

### (Block Configuration of Imaging Element 101)

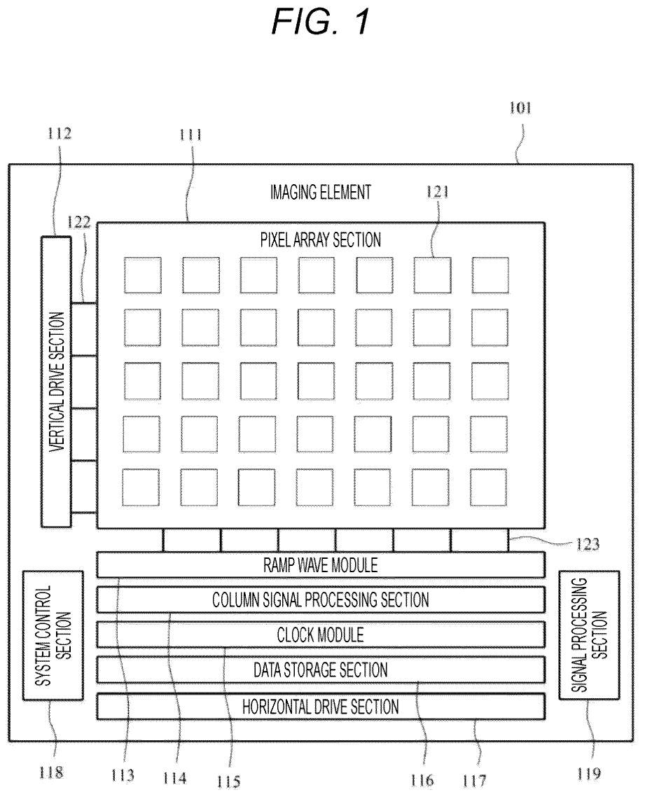

FIG. 1 is a block diagram illustrating a schematic configuration of the imaging element 101 of the present embodiment.

Since the imaging element 101 of the present embodiment is formed on a semiconductor substrate 11, the imaging element is accurately a solid-state imaging element, but is simply referred to as an imaging element below.

The imaging element 101 includes, for example, a pixel array section 111, a vertical drive section 112, a ramp wave module 113, a column signal processing section 114, a clock module 115, a data storage section 116, a horizontal drive section 117, a system control section 118, and a signal processing section 119.

The pixel array section 111 includes a plurality of sensor pixels 121 each including a photoelectric conversion element that generates and accumulates a charge corresponding to an amount of light that has entered from a subject. As illustrated in FIG. 1, the plurality of sensor pixels 121 are arranged in a lateral direction (row direction) and a longitudinal direction (column direction). The sensor pixel 121 corresponds to a pixel of the imaging element 101.

Furthermore, the pixel array section 111 includes a pixel drive line 122 and a vertical signal line 123. The pixel drive line 122 is wired along the row direction for each pixel row including the sensor pixels 121 arranged in one row in the row direction. The vertical signal line 123 is wired along the column direction for each pixel column including the sensor pixels 121 arranged in one column in the column direction.

The vertical drive section 112 includes a shift register, an address decoder, and the like. The vertical drive section 112 supplies a signal or the like to the plurality of sensor pixels 121 via a plurality of the pixel drive lines 122 to drive all of the plurality of sensor pixels 121 in the pixel array section 111 at the same time or in units of pixel rows.

The ramp wave module 113 generates a ramp wave signal to be used for analog/digital (A/D) conversion of pixel signals, and supplies the ramp wave signal to the column signal processing section 114.

The column signal processing section 114 includes a shift register, an address decoder, and the like, and performs denoising processing, correlated double sampling processing, A/D conversion processing, and the like, to generate a pixel signal. The column signal processing section 114 supplies the generated pixel signal to the signal processing section 119.

The clock module 115 supplies a clock signal for operation to each component of the imaging element 101.

The horizontal drive section 117 sequentially selects unit circuits corresponding to the pixel columns in the column signal processing section 114. The selective scanning is performed by the horizontal drive section 117 so that the pixel signals subjected to signal processing for each unit circuit in the column signal processing section 114 are sequentially output to the signal processing section 119.

The system control section 118 includes a timing generator or the like that generates various timing signals. The system control section 118 controls driving of the vertical drive section 112, the ramp wave module 113, the column signal processing section 114, the clock module 115, and the horizontal drive section 117 on the basis of the timing signals generated by the timing generator.

The signal processing section 119 performs signal processing such as arithmetic processing on pixel signals supplied from the column signal processing section 114 while temporarily storing data in the data storage section 116 as necessary, and outputs an image signal including the respective pixel signals.

The imaging element 101 includes a single or a plurality of semiconductor substrates 11. For example, the imaging element 101 can be configured by forming the vertical drive section 112, the ramp wave module 113, the column signal processing section 114, the clock module 115, the data storage section 116, the horizontal drive section 117, the system control section 118, the signal processing section 119, and the like on another semiconductor substrate and electrically connecting the another semiconductor substrate to the semiconductor substrate 11 on which the pixel array section 111 is formed by Cu—Cu bonding or the like. Furthermore, some of the elements constituting the pixel array section 111 can be formed on the another semiconductor substrate.

### (Circuit Configuration of Sensor Pixel 121)

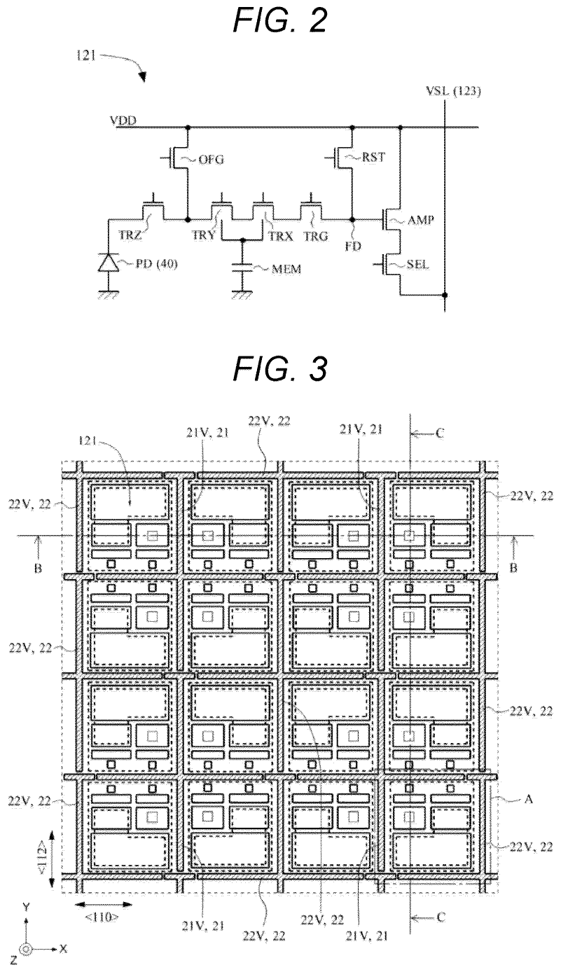

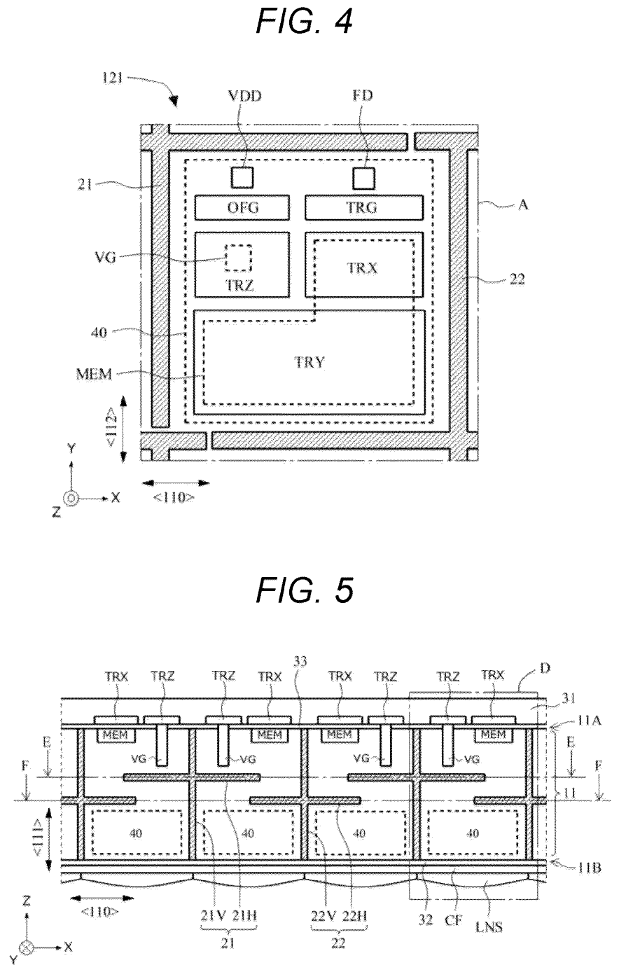

FIG. 2 is an equivalent circuit diagram of the sensor pixel 121. FIG. 3 is a planar layout diagram illustrating some pixel regions in the pixel array section. FIG. 3 illustrates a 4×4, 16-pixel region. FIG. 4 is a planar layout diagram illustrating a pixel region for one pixel, and illustrates a region A in FIG. 3.

As illustrated in FIGS. 2 and 4, the sensor pixel 121 includes a photoelectric conversion section 40, a charge holding section MEM, four transfer transistors TRZ, TRY, TRX, and TRG, a discharge transistor OFG, a reset transistor RST, an amplification transistor AMP, and a selection transistor SEL.

Note that the reset transistor RST, the amplification transistor AMP, and the selection transistor SEL are not illustrated in the planar layout diagrams of FIGS. 3 and 4. This is because, in the examples illustrated in FIGS. 3 and 4, these transistors are formed on a semiconductor substrate different from the semiconductor substrate 11 on which the main portions of the pixel array section 111 are disposed.

The photoelectric conversion section 40 includes, for example, a photodiode (PD) and generates a charge according to an amount of received light by photoelectric conversion.

The charge holding section MEM is a region that temporarily holds the charge generated and accumulated in the photoelectric conversion section 40 in order to achieve the global shutter function. The charge holding section MEM holds the charge transferred from the photoelectric conversion section 40.

The transfer transistor TRZ is connected to the photoelectric conversion section 40 in the sensor pixel 121, and transfers the charge (pixel signal) photoelectrically converted by the photoelectric conversion section 40 to the transfer transistor TRY. The transfer transistor TRZ is a vertical transistor, and includes a vertical gate electrode VG.

The transfer transistor TRY transfers to the transfer transistor TRX the charge transferred from the transfer transistor TRZ. The transfer transistors TRY and TRX may be replaced with one transfer transistor. The charge holding section MEM is connected to the transfer transistors TRY and TRX. The potential of the charge holding section MEM is controlled by a control signal applied to the gate electrodes of the transfer transistors TRY and TRX.

For example, when the transfer transistors TRY and TRX are turned on, the potential of the charge holding section MEM becomes deeper, and when the transfer transistors TRY and TRX are turned off, the potential of the charge holding section MEM becomes shallower. Then, when the transfer transistors TRZ, TRY, and TRX are turned on, for example, the charge accumulated in the photodiode 40 is transferred to the charge holding section MEM via the transfer transistors TRZ, TRY, and TRX.

The drain of the transfer transistor TRX is electrically connected to the source of the transfer transistor TRG. The gates of the transfer transistors TRY and TRX are electrically connected to the pixel drive line 122.

The transfer transistor TRG is connected between the transfer transistor TRX and a floating diffusion region FD. The transfer transistor TRG transfers the charge held in the charge holding section MEM to the floating diffusion region FD according to a control signal applied to the gate electrode.

For example, when the transfer transistor TRX is turned off and the transfer transistor TRG is turned on, the charge held in the charge holding section MEM is transferred to the floating diffusion region FD. The drain of the transfer transistor TRG is electrically connected to the floating diffusion region FD. The gate of the transfer transistor TRG is electrically connected to the pixel drive line 122.

The floating diffusion region FD is a floating diffusion region that temporarily holds the charge output from the photoelectric conversion section 40 via the transfer transistor TRG. The reset transistor RST is, for example, connected to the floating diffusion region FD, and the vertical signal line VSL (123) is connected to the floating diffusion region via the amplification transistor AMP and the selection transistor SEL.

The discharge transistor OFG initializes (resets) the photoelectric conversion section 40 according to a control signal applied to the gate electrode. The drain of the discharge transistor OFG is connected to a power supply line VDD. The source of the discharge transistor OFG is connected between the transfer transistor TRZ and the transfer transistor TRY.

For example, when the transfer transistor TRZ and the discharge transistor OFG are turned on, the potential of the photoelectric conversion section 40 is reset to a potential level of the power supply line VDD. That is, the photoelectric conversion section 40 is initialized. Furthermore, for example, the discharge transistor OFG forms an overflow path between the transfer transistor TRZ and the power supply line VDD, and discharges charges overflowing from the photoelectric conversion section 40 to the power supply line VDD.

The reset transistor RST initializes (resets) each region from the charge holding section MEM to the floating diffusion region FD according to a control signal applied to the gate electrode. The drain of the reset transistor RST is electrically connected to the power supply line VDD. The source of the reset transistor RST is connected to the floating diffusion region FD.

For example, when the transfer transistor TRG and the reset transistor RST are turned on, the potentials of the charge holding section MEM and the floating diffusion region FD are reset to a potential level of the power supply line VDD. That is, turning on the reset transistor RST initializes the charge holding section MEM and the floating diffusion region FD.

The amplification transistor AMP includes a gate electrode connected to the floating diffusion region FD and a drain connected to the power supply line VDD, and serves as an input section of a source-follower circuit that reads the charge obtained by the photoelectric conversion in the photoelectric conversion section 40. That is, the amplification transistor AMP includes a source connected to the vertical signal line VSL (123) via the selection transistor SEL, thereby forming the source-follower circuit with a constant current source connected to one end of the vertical signal line VSL (123).

The selection transistor SEL is connected between the source of the amplification transistor AMP and the vertical signal line VSL (123). A control signal is supplied to a gate electrode of the selection transistor SEL as a selection signal. When the control signal is turned on, the selection transistor SEL enters a conductive state, and the sensor pixel 121 coupled to the selection transistor SEL enters a selected state. As the sensor pixel 121 enters the selected state, the pixel signal output from the amplification transistor AMP is read out by the column signal processing section 114 via the vertical signal line VSL (123).

As illustrated in FIGS. 3 and 4, the transfer transistors TRG, TRX, TRY, and TRZ and the discharge transistor OFG of one sensor pixel 121 are disposed in order in a U shape in the sensor pixel 121. The arrangement of each transistor of the two sensor pixels 121 adjacent in the Y direction is line-symmetric with respect to a boundary between the two sensor pixels 121. The arrangement of each transistor of the two sensor pixels 121 adjacent in the X direction is line-symmetric with respect to a boundary between the two sensor pixels 121.

The charge holding section MEM is disposed below the transfer transistors TRX and TRY. Furthermore, the photoelectric conversion section 40 in one sensor pixel 121 is disposed over the entire area of the sensor pixel 121.

The planar layout of the respective transistors in the sensor pixel 121 is not necessarily limited to those illustrated in FIGS. 3 and 4. When the arrangement of the respective transistors in the sensor pixel 121 is changed, the locations of the photoelectric conversion section 40 and the charge holding section MEM disposed below those transistors are also changed.

### (Cross-Sectional Structure of Imaging Element 101)

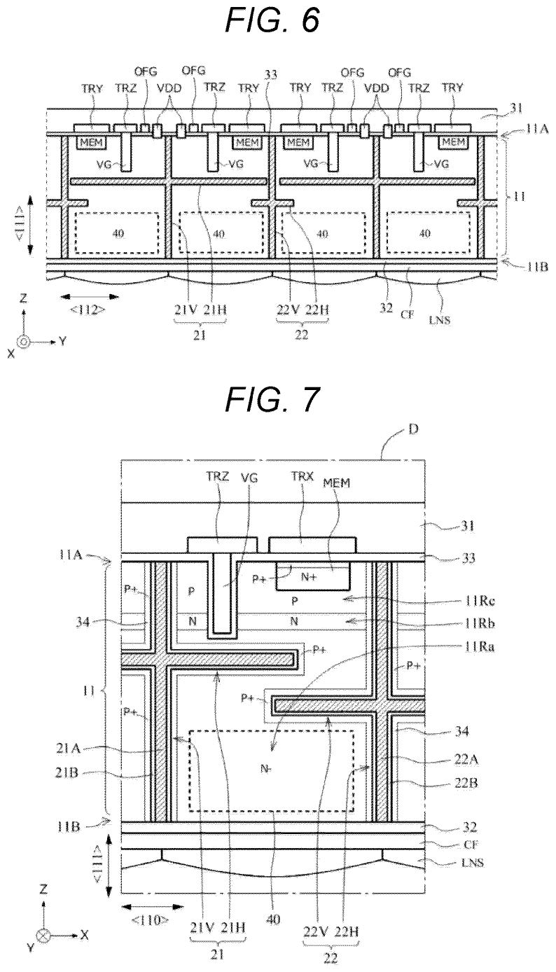

FIG. 5 is a longitudinal cross-sectional view illustrating a cross-sectional structure of the imaging element 101, and illustrates a cross section taken along line B-B in FIG. 3. FIG. 6 is a longitudinal cross-sectional view illustrating a cross-sectional structure of the imaging element 101, and illustrates a cross section taken along line C-C in FIG. 3. FIG. 7 is a longitudinal cross-sectional view illustrating details of a cross-sectional structure of the imaging element 101, and illustrates a region D in FIG. 5.

Symbols “P” and “N” in FIG. 7 represent a P type semiconductor region and an N type semiconductor region, respectively. Moreover, “+” or “−” at the end of each symbol of “P++”, “P+”, “P−”, and “P−−” represents an impurity concentration of a P type semiconductor region. Similarly, “+” or “−” at the end of each symbol of “N++”, “N+”, “N−”, and “N−−” represents an impurity concentration of an N type semiconductor region. Here, a larger number of “+” indicates a higher impurity concentration, and a larger number of “−” indicates a lower impurity concentration. The similarity applies to the subsequent drawings.

The imaging element 101 illustrated in FIGS. 5 to 7 includes the semiconductor substrate 11, the photoelectric conversion section 40, the charge holding section MEM, the transfer transistors TRZ, TRY, TRX, and TRG, the discharge transistor OFG, the floating diffusion region FD, a first light shielding section 21, a second light shielding section 22, a wiring layer 31, a fixed charge film 32, a color filter CF, and a light receiving lens LNS. The transfer transistor TRZ includes the vertical gate electrode VG which is a vertical electrode.

In the present specification, one principal surface of the semiconductor substrate 11 on a side where the wiring layer 31 is disposed is referred to as a first surface 11A, and one principal surface on a side where the light receiving lens LNS is disposed is referred to as a second surface 11B or light receiving surface. The first surface 11A is a surface opposite to a light incident surface of the semiconductor substrate 11. The second surface 11B is the light incident surface of the semiconductor substrate 11. Furthermore, in the present specification, the first surface 11A may be referred to as a “front surface”, and the second surface 11B may be referred to as a “back surface”.

In the imaging element 101 of the present embodiment, a single-crystal silicon substrate in which the first surface 11A is a crystal plane having a plane index {111} is used as the semiconductor substrate 11. One of the reasons is that the first light shielding section 21 and the second light shielding section 22 described later are formed using crystal anisotropic wet etching. Details of the crystal anisotropic wet etching will be described later.

The semiconductor substrate 11 includes therein an N− type semiconductor region 11Ra, an N type semiconductor region 11Rb, and a P type semiconductor region 11Rc in this order from a position close to the second surface 11B (see FIG. 7). The three layers form a photodiode. A part of the N− type semiconductor region 11Ra of the photodiode serves as the photoelectric conversion section 40.

After light incident on the second surface 11B is photoelectrically converted in the photoelectric conversion section of the N− type semiconductor region 11Ra to generate a charge, the charge is accumulated in the N type semiconductor region 11Rb. Note that a boundary between the N− type semiconductor region 11Ra and the N type semiconductor region 11Rb is not necessarily clear, and an N type impurity concentration is only required to increase gradually in a direction from the N− type semiconductor region 11Ra toward the N type semiconductor region 11Rb, for example. Furthermore, a P+ type semiconductor region having a higher P type impurity concentration than that of the P type semiconductor region 11Rc may be provided between the N type semiconductor region and the P type semiconductor region 11Rc. As described above, the configuration of the photoelectric conversion section 40 is not necessarily limited to those illustrated in FIGS. 5 to 7.

The charge holding section MEM is configured as an N+ type semiconductor region provided in the P type semiconductor region 11Rc (see FIG. 7). In the example illustrated in FIG. 7, a P+ semiconductor region is formed between the N+ type semiconductor region and the first surface 11A of the semiconductor substrate 11. The P+ type semiconductor region has an effect of pinning a surface level of the semiconductor substrate 11 and suppressing a dark current.

The transfer transistor TRZ includes the vertical gate electrode VG extending in a direction (Z direction) orthogonal to the first surface 11A of the semiconductor substrate 11. An insulating layer 33 is provided around the vertical gate electrode VG. The deepest location of the vertical gate electrode VG is in the N− type semiconductor region 11Ra, for example. The transfer transistor TRZ transfers the charge photoelectrically converted by the photoelectric conversion section 40 to the transfer electrode TRY via the vertical gate electrode VG.

The respective gate electrodes of the transfer transistors TRZ, TRY, TRX, and TRG and the discharge transistor OFG are all provided on a side of the first surface 11A of the semiconductor substrate 11 via the insulating layer 33.

The floating diffusion region FD is configured as an N++ type semiconductor region provided in the P type semiconductor region 11Rc. Note that the floating diffusion region FD does not exist in a region corresponding to the B-B cross section and the C-C cross section in FIG. 3, and thus, is not illustrated in FIGS. 5 to 7.

The first light shielding section 21 and the second light shielding section 22 are portions having a light shielding property. The first light shielding section 21 and the second light shielding section 22 have a function of absorbing or reflecting light.

The first light shielding section 21 and the second light shielding section 22 include vertical light shielding sections 21V and 22V that spread in a wall shape in a direction orthogonal to the first surface 11A of the semiconductor substrate 11, and horizontal light shielding sections 21H and 22H that spread in a plate shape in a direction parallel to the first surface 11A of the semiconductor substrate 11.

One of the features of the imaging element 101 of the present embodiment is that it includes the first light shielding section 21 and the second light shielding section 22 having specific configurations. Furthermore, one of the features of the imaging element 101 of the present embodiment is that it has a multi-stage light shielding structure, and has a hexagonal shielding structure in which each stage is independent in an arbitrary in-plane direction. Specific configurations of the first light shielding section 21 and the second light shielding section 22 will be described later.

The wiring layer 31 is a layer in which various wirings are formed, and is provided on the first surface 11A side of the semiconductor substrate 11. The wiring layer 31 may be formed by bonding another circuit board.

As illustrated in FIGS. 5 to 7, the fixed charge film 32 is stacked on the second surface 11B of the semiconductor substrate 11. The fixed charge film 32 has a negative fixed charge in order to prevent occurrence of a dark current caused by an interface state of the second surface 11B that is the light receiving surface of the semiconductor substrate 11. A hole accumulation layer is formed in the vicinity of the second surface 11B of the semiconductor substrate 11 by an electric field induced by the fixed charge film 32. This hole accumulation layer prevents generation of electrons from the second surface 11B.

As illustrated in FIGS. 5 to 7, the color filter CF is disposed below the fixed charge film 32 (in a −Z direction), and the light receiving lens LNS is disposed below the color filter CF (in the −Z direction). The color filter CF and the light receiving lens LNS are provided for each sensor pixel 121.

### (Specific Configurations of First Light Shielding Section 21 and Second Light Shielding Section 22)

Next, specific configurations of the first light shielding section 21 and the second light shielding section 22 will be described.

As described above, one of the features of the imaging element 101 of the present embodiment is that it has a multi-stage light shielding structure, and has a hexagonal shielding structure in which each stage is independent in any in-plane direction.

As illustrated in FIG. 7, the first light shielding section 21 and the second light shielding section 22 include light shielding material portions 21A and 22A and insulating films 21B and 22B covering the periphery thereof.

The light shielding material portions 21A and 22A include, for example, a material containing at least one of a single metal, a metal alloy, a metal nitride, or a metal silicide having a light shielding property. More specifically, examples of a material constituting the light shielding material portions 21A and 22A include W (tungsten), Ti (titanium), Ta (tantalum), Ni (nickel), Mo (molybdenum), Cr (chromium), Ir (iridium), platinum iridium, TiN (titanium nitride), Al (aluminum), Cu (copper), Co (cobalt), a tungsten silicon compound, or the like. Note that the material constituting the light shielding material portions 21A and 22A are not limited thereto. For example, it is also possible to use a substance having a light shielding property other than metal, such as carbon, an oxide film, or an electromic material.

The insulating films 21B and 22B include an insulating material such as SiO₂ (silicon oxide), for example. The insulating films 21B and 22B ensure electrical insulation between the light shielding material portions 21A and 22A and the semiconductor substrate 11.

Furthermore, a pinning layer 34 formed as a P type semiconductor region is provided in a region around the first light shielding section 21 and the second light shielding section 22 in the semiconductor substrate 11 (see FIG. 7). In the example illustrated in FIG. 7, the pinning layer 34 is formed as a P+ type semiconductor region. The pinning layer 34 has an effect of fixing the surface levels of the first light shielding section 21 and the second light shielding section 22 and suppressing dark current. Furthermore, the pinning layer 34 has an effect of improving the saturation charge amount (Qs) of the imaging element 101.

As described above, the first light shielding section 21 and the second light shielding section 22 include the vertical light shielding sections 21V and 22V that spread in a wall shape in the direction orthogonal to the first surface 11A of the semiconductor substrate 11 and the horizontal light shielding sections 21H and 22H that spread in a plate shape in the direction parallel to the first surface 11A of the semiconductor substrate 11.

Both of the vertical light shielding sections 21V and 22V of the first light shielding section 21 and the second light shielding section 22 are formed so as to penetrate the semiconductor substrate 11.

The horizontal light shielding section 21H of the first light shielding section 21 and the horizontal light shielding section 22H of the second light shielding section 22 are arranged at different positions in the direction (Z direction) orthogonal to the first surface 11A of the semiconductor substrate 11. The horizontal light shielding section 21H of the first light shielding section 21 is disposed closer to the first surface 11A of the semiconductor substrate 11 than the horizontal light shielding section 22H of the second light shielding section 22. In other words, the horizontal light shielding section 22H of the second light shielding section 22 is disposed closer to the second surface 11B of the semiconductor substrate 11 than the horizontal light shielding section 21H of the first light shielding section 21.

Furthermore, the horizontal light shielding section 21H of the first light shielding section 21 is disposed closer to the second surface 11B of the semiconductor substrate 11 than the vertical gate electrode VG of the transfer transistor TRZ in the direction (Z direction) orthogonal to the first surface 11A of the semiconductor substrate 11. In other words, the vertical gate electrode VG of the transfer transistor TRZ is disposed closer to the first surface 11A of the semiconductor substrate 11 than the horizontal light shielding section 21H of the first light shielding section 21 in the direction (Z direction) orthogonal to the first surface 11A of the semiconductor substrate 11. Effects of this configuration will be described later.

As illustrated in FIG. 3, the vertical light shielding sections 21V and 22V of the first light shielding section 21 and the second light shielding section 22 are disposed along a boundary portion of the plurality of sensor pixels 121 arranged in an orthogonal lattice pattern in a plan view. Here, the plan view means viewing from a direction (Z direction) orthogonal to the first surface 11A of the semiconductor substrate 11.

The first light shielding section 21 is independently disposed for every 2×2 four sensor pixels 121. That is, the imaging element 101 includes the plurality of first light shielding sections 21 arranged independently for each of the four 2×2 sensor pixels 121. Here, 2×2 means a state in which two sensor pixels are arranged in the X direction and two sensor pixels 121 are arranged in the Y direction.

Similarly, the second light shielding section 22 is arranged independently for each of the four 2×2 sensor pixels 121. That is, the imaging element 101 includes the plurality of second light shielding sections 22 arranged independently for each of the four 2×2 sensor pixels 121.

Note that the 4×4 sensor pixels 121 in which the second light shielding section 22 is arranged are not the same as the 4×4 sensor pixels 121 in which the first light shielding section 21 is arranged. The 4×4 sensor pixels 121 in which the second light shielding section 22 is arranged are selected by being shifted by one sensor pixel 121 in each of the X direction and the Y direction illustrated in FIG. 3.

The vertical light shielding section 21V of the first light shielding section 21 is disposed on two adjacent sides among the four sides around each sensor pixel 121, and the vertical light shielding section 22V of the second light shielding section 22 is disposed on the other two sides. That is, the vertical light shielding sections 21V and 22V of the first light shielding section 21 and the second light shielding section 22 are disposed so as to surround each sensor pixel 121 by the vertical light shielding section 21V of the first light shielding section 21 and the vertical light shielding section 22V of the second light shielding section 22.

Specifically, the horizontal light shielding section 21V of the first light shielding section 21 is disposed along a boundary portion of the four 2×2 sensor pixels 121. The horizontal light shielding section 21V of the first light shielding section 21 has a portion extending in a <112> direction and a portion extending in a <110> direction in plan view. The horizontal light shielding section 21V of the first light shielding section 21 has a shape in which a portion extending in the <112> direction and a portion extending in the <110> direction intersect in a cross shape in plan view.

The <112> direction refers to a crystal direction of an orientation index <112> of the semiconductor substrate 11. Furthermore, the <110> direction refers to a crystal direction of an orientation index <110> of the semiconductor substrate 11. In the description of the present specification, the <112> direction corresponds to the Y direction, and the <110> direction corresponds to the X direction.

The reason why the horizontal light shielding section 21V of the first light shielding section 21 has the portion extending in the <112> direction and the portion extending in the <110> direction is that the first light shielding section 21 is formed using crystal anisotropic wet etching. Details of the crystal anisotropic wet etching will be described later.

A portion of the horizontal light shielding section 21V extending in the <112> direction is disposed along a boundary portion between the two left sensor pixels 121 and the two right sensor pixels 121 of the four 2×2 sensor pixels 121. A portion of the horizontal light shielding section 21V extending in the <110> direction is disposed along a boundary portion between the upper two sensor pixels 121 and the lower two sensor pixels 121 of the four 2×2 sensor pixels 121.

Furthermore, the horizontal light shielding section 21V of the first light shielding section 21 has a part that is connected to the end on the Y direction side of the part that extends in the <112> direction and that extends short in the <110> direction. This portion is provided to cover a gap between the vertical light shielding section 21V of the first light shielding section 21 and the vertical light shielding section 22V of the second light shielding section 22.

Similarly, the vertical light shielding section 22V of the second light shielding section 22 is disposed along the boundary portion of the four 2×2 sensor pixels 121. The vertical light shielding section 22V of the second light shielding section 22 has a portion extending in the <112> direction and a portion extending in the <110> direction in plan view. Then, the vertical light shielding section 22V of the second light shielding section 22 has a shape in which a portion extending in the <112> direction and a portion extending in the <110> direction cross each other in a cross shape in plan view. Furthermore, the vertical light shielding section 22V has a portion that extends short in the <110> direction and is connected to the end on the Y direction side of the portion extending in the <112> direction.

As described above, the vertical light shielding sections 21V and 22V of the first light shielding section 21 and the second light shielding section 22 are disposed so as to surround each sensor pixel 121. Furthermore, the first light shielding section 21 and the second light shielding section 22 are disposed such that a gap between the vertical light shielding section 21V of the first light shielding section 21 and the vertical light shielding section 22V of the second light shielding section 22 is located at a corner of the sensor pixel 121. Therefore, in the imaging element 101 of the present embodiment, crosstalk between the adjacent sensor pixels 121 is suppressed, and as a result, occurrence of color mixture and blooming is suppressed.

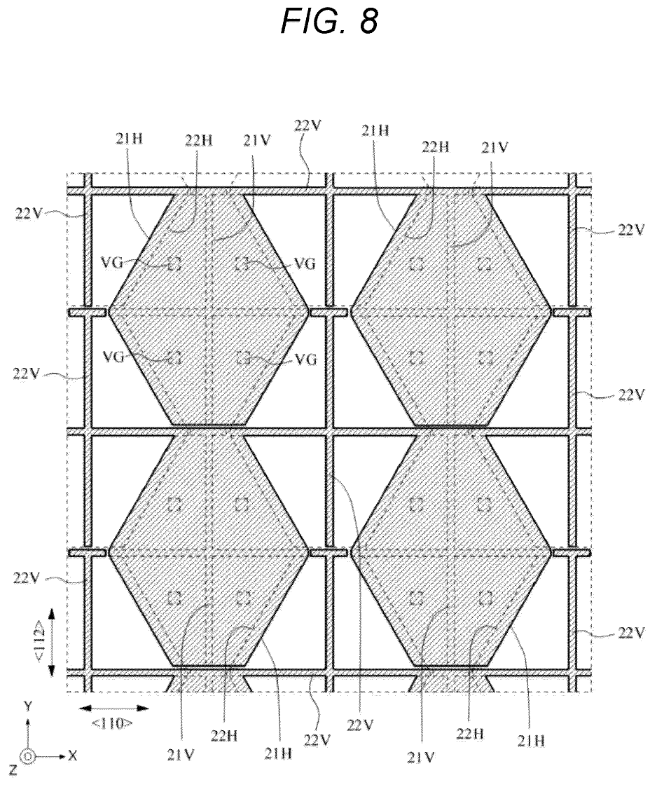

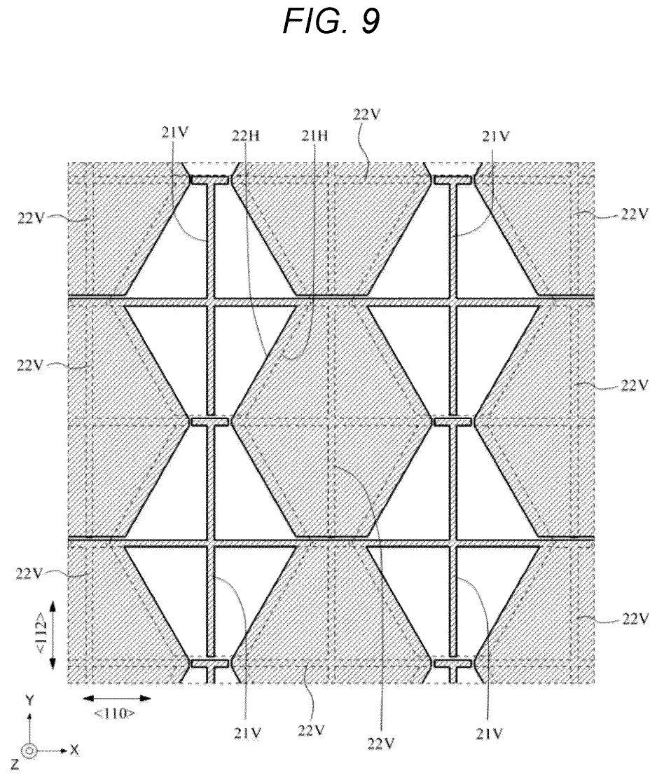

FIG. 8 is a transverse cross-sectional view illustrating a configuration of the horizontal light shielding section 21H of the first light shielding section 21, and illustrates a cross section taken along line E-E in FIG. 5. FIG. 9 is a transverse cross-sectional view illustrating a configuration of the horizontal light shielding section 22H of the second light shielding section 22, and illustrates a cross section taken along line F-F in FIG. 5.

As illustrated in FIG. 8, the horizontal light shielding section 21H of the first light shielding section 21 has a hexagonal shape in plan view. That is, the first light shielding section 21 includes the horizontal light shielding section 21H having a hexagonal shape in plan view.

Similarly, as illustrated in FIG. 9, the horizontal light shielding section 22H of the second light shielding section 22 has a hexagonal shape in plan view. That is, the second light shielding section 22 has the horizontal light shielding section 22H having a hexagonal shape in plan view.

The hexagon of each of the horizontal light shielding sections 21H and 22H has six sides extending in the <110> direction. Furthermore, the six interior angles of the hexagon are all 120°. That is, the horizontal light shielding sections 21H and 22H of the first light shielding section 21 and the second light shielding section have a hexagonal shape in plan view. Then, the hexagon has six sides extending in the <110> directions. Furthermore, the interior angles of the hexagons are all 120°. Note that, although FIGS. 8 and 9 illustrate that the X direction corresponds to the <110> direction, a direction obtained by rotating the X direction by 60° or 120° around the Z direction also corresponds to the <110> direction.

As described later, the horizontal light shielding sections 21H and 22H are formed by autonomous shape control without using an etching stopper or the like. Therefore, the imaging element 101 of the present embodiment has few lattice defects, and as a result, the occurrence of white spots and blinking points is suppressed.

The horizontal light shielding section 21H of the first light shielding section 21 and the horizontal light shielding section 22H of the second light shielding section 22 are disposed such that their peripheral edges overlap each other in the sensor pixel 121 in plan view. In other words, the horizontal light shielding section 22H of the second light shielding section 22 is arranged so as to cover a region where the horizontal light shielding section 21H of the first light shielding section 21 is not arranged in plan view. Furthermore, the horizontal light shielding section 21H of the first light shielding section 21 is arranged so as to cover a region where the horizontal light shielding section 22H of the second light shielding section 22 is not arranged in plan view. With this configuration, light that has not been photoelectrically converted by the photoelectric conversion section 40 can be suppressed from entering the charge holding section MEM or the wiring layer 31.

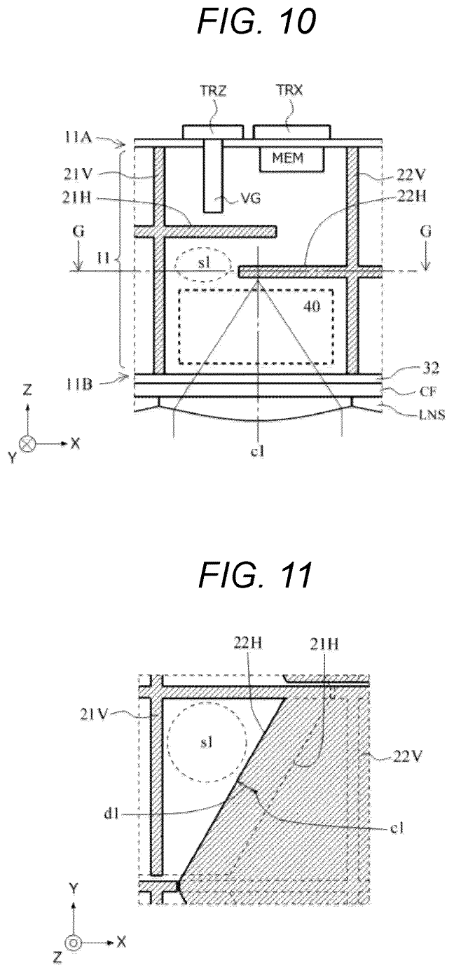

FIG. 10 is a longitudinal cross-sectional view illustrating a positional relationship between the horizontal light shielding sections 21H and 22H of the first light shielding section 21 and the second light shielding section 22 and a light condensing center c1 of the imaging element 101. FIG. 11 is a transverse cross-sectional view illustrating a positional relationship between the horizontal light shielding sections 21H and 22H of the first light shielding section 21 and the second light shielding section 22 and the light condensing center c1 of the imaging element 101, and illustrates a cross section taken along line G-G in FIG. 10.

In the imaging element 101 of the present embodiment, since the horizontal light shielding sections 21H and 22H have a hexagonal shape, as illustrated in FIG. 11, the charge transfer space s1, which is a region to which charge is transferred, is arranged in a region of a corner portion of the sensor pixel 121. Therefore, an overlap amount d1 of the horizontal light shielding sections 21H and 22H is large.

Here, as illustrated in FIG. 11, the overlap amount d1 refers to the shortest distance from the light condensing center c1 to the edge portions of the horizontal light shielding sections 21H and 22H in plan view. FIG. 11 illustrates the overlap amount d1 of the horizontal light shielding section 22H of the second light shielding section 22, but the overlap amount d1 of the horizontal light shielding section 21 of the first light shielding section 21 is similarly defined.

The charge transfer amount, which is the amount of charges that can pass through the charge transfer space s1, decreases as the overlap amount d1 of the horizontal light shielding sections 21H and 22H increases, and increases as the overlap amount d1 decreases. That is, the charge transfer amount and the overlap amount d1 of the horizontal light shielding sections 21H and 22H are in a trade-off relationship.

However, in the imaging element 101 of the present embodiment, since the charge transfer space s1 is arranged in the region of the corner portion of the sensor pixel 121 as described above, it is possible to increase the overlap amount d1 of the horizontal light shielding sections 21H and 22H.

In this regard, in the conventional imaging element, the distal end portion of the vertical gate electrode VG is located closer to the second surface 11B of the semiconductor substrate 11 than the light shielding section spreading in the in-plane direction of the semiconductor substrate 11 (See, for example, FIG. 4 of Patent Document 1 and FIG. 3 of Patent Document 2). In the case of such a configuration, the presence of the vertical gate electrode VG becomes an obstacle when the overlap amount d1 of the horizontal light shielding section 21H of the first light shielding section 21 is increased.

However, as described above, in the imaging element 101 of the present embodiment, the vertical gate electrode VG of the transfer transistor TRZ is disposed closer to the first surface 11A of the semiconductor substrate 11 than the horizontal light shielding section 21H of the first light shielding section 21 in the direction (Z direction) orthogonal to the first surface 11A of the semiconductor substrate 11. Here, the vertical gate electrode VG being disposed closer to the first surface 11A of the semiconductor substrate 11 than the horizontal light shielding section 21H means that the tip of the vertical gate electrode VG is located closer to the first surface 11A of the semiconductor substrate 11 than the horizontal light shielding section 21H, and there is no light shielding section having a horizontal light shielding section closer to the first surface 11A of the semiconductor substrate 11 than the tip of the vertical gate electrode VG. This configuration is found as a result of research by the disclosures of the present disclosure.

With this configuration, the presence of the vertical gate electrode VG does not become an obstacle when the overlap amount d1 of the horizontal light shielding section 21H of the first light shielding section 21 is increased.

As described above, in the imaging element 101 of the present embodiment, the overlap amount d1 of the horizontal light shielding sections 21H and 22H of the first light shielding section 21 and the second light shielding section 22 is large, and eventually, the parasitic light sensitivity (PLS) is suppressed to be low. Furthermore, since the trade-off relationship between the charge transfer amount and the overlap amount d1 of the horizontal light shielding sections 21H and 22H is reduced, it is advantageous for miniaturization of the imaging element 101.

To summarize the above, the imaging element 101 of the present embodiment includes the semiconductor substrate 11 including the first surface 11A and the second surface 11B, and the photoelectric conversion section 40, the charge holding section MEM, the first light shielding section 21, and the second light shielding section 22 disposed in the semiconductor substrate 11. The first light shielding section 21 and the second light shielding section 22 respectively include the vertical light shielding sections 21V and 22V that spread in a wall shape in a direction orthogonal to the first surface 11A, and the horizontal light shielding sections 21H and 22H that spread in a plate shape in a direction parallel to the first surface 11A. The horizontal light shielding sections 21H and 22H have a hexagonal shape when viewed from the direction orthogonal to the first surface 11A. The photoelectric conversion section 40 is disposed on the second surface 11B side of the horizontal light shielding section 21H of the first light shielding section 21. The charge holding section MEM is disposed on the first surface 11A side of the horizontal light shielding section 21V of the first light shielding section 21. The horizontal light shielding section 22H of the second light shielding section 22 is disposed closer to the second surface 22B than the horizontal light shielding section 21H of the first light shielding section 21, and is disposed so as to cover a region where the horizontal light shielding section 21H of the first light shielding section 21 is not disposed when viewed from the direction orthogonal to the first surface 11A.

In such an imaging element 101, generation of noise caused by crosstalk, dark current, lattice defects, PLS, or the like is suppressed.

Note that, in the imaging element 101 of the present embodiment described above, the horizontal light shielding section 21H of the first light shielding section 21 and the horizontal light shielding section 22H of the second light shielding section 22 overlap, but the imaging element 101 of the present disclosure is not limited to such a configuration. Even in the imaging element 101 in which the horizontal light shielding section 21H of the first light shielding section 21 and the horizontal light shielding section 22H of the second light shielding section 22 do not overlap, as described above, the number of lattice defects is small, and as a result, the occurrence of white points and blinking points is suppressed.

### 2. Manufacturing Method of Imaging Element of Present Embodiment

Next, an example of a manufacturing method of the imaging element 101 will be described.

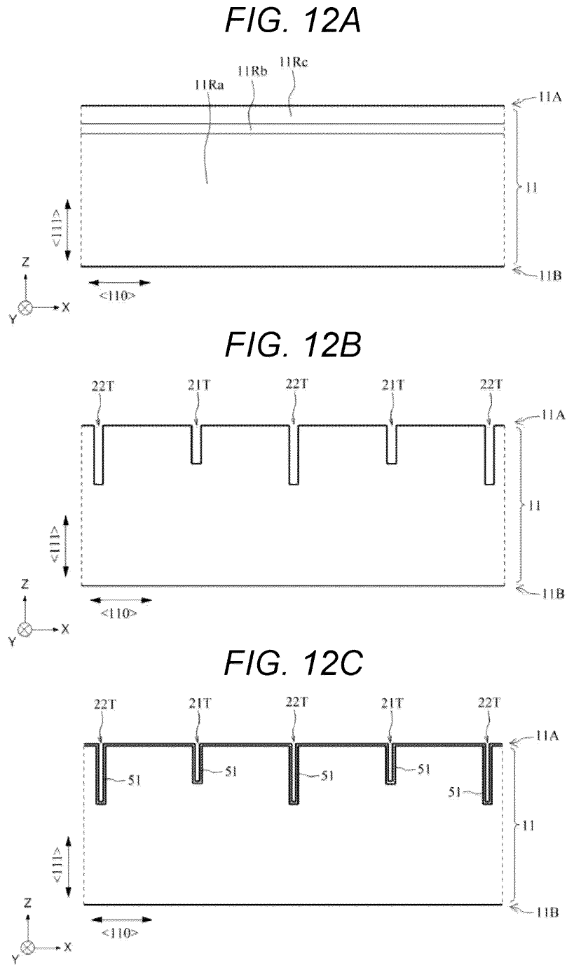

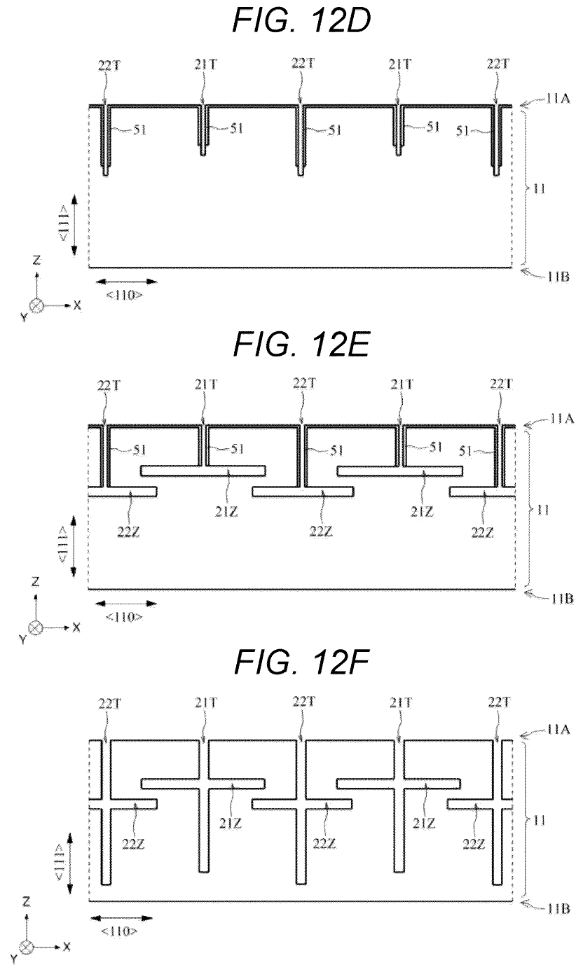

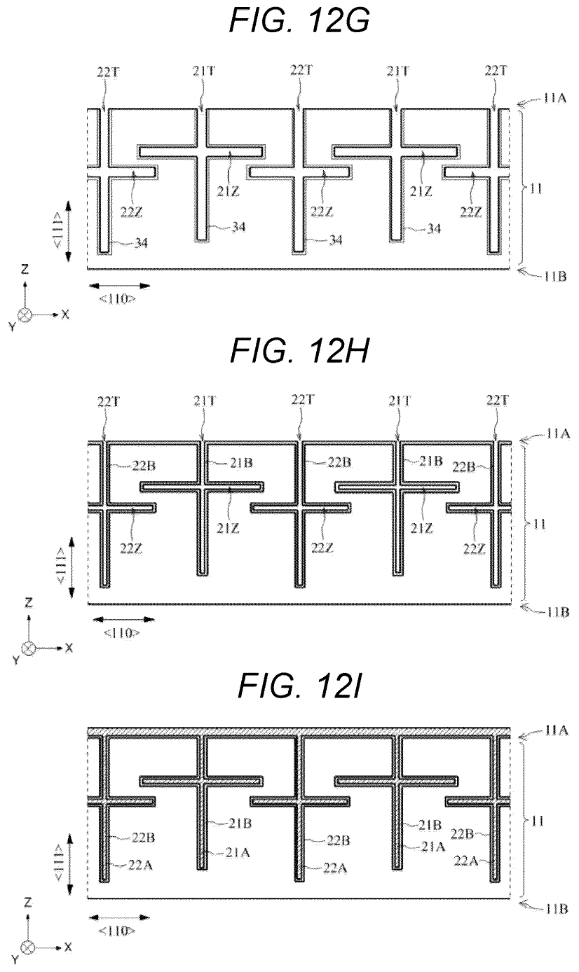

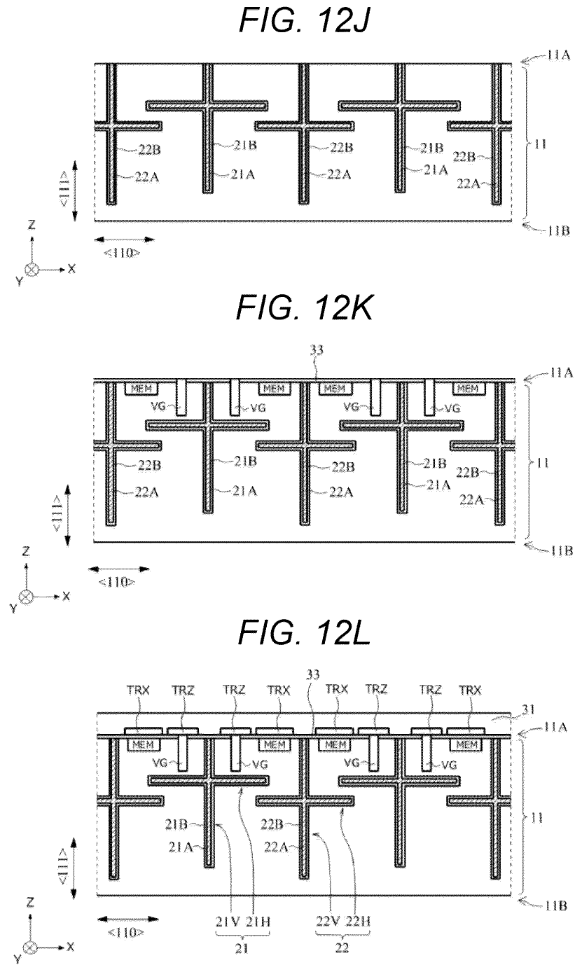

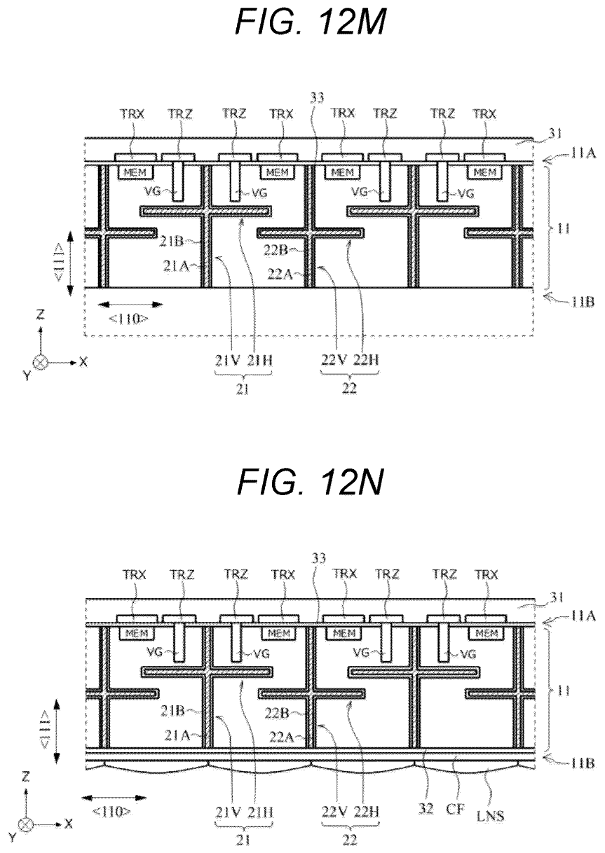

FIGS. 12A to 12N are longitudinal cross-sectional views illustrating an example of a manufacturing method of the imaging element 101.

First, as illustrated in FIG. 12A, the N− type semiconductor region 11Ra, the N type semiconductor region 11Rb, and the P type semiconductor region 11Rc are formed on the semiconductor substrate 11. The semiconductor substrate 11 is a single-crystal silicon substrate having a crystal orientation of a plane index {111}. Note that, in the following FIGS. 12B to 12N, the N− type semiconductor region 11Ra, the N type semiconductor region 11Rb, and the P type semiconductor region 11Rc are not illustrated.

Next, as illustrated in 12B, trenches 21T and 22T are formed in accordance with the positions of the vertical light shielding sections 21V and 22V of the first light shielding section 21 and the second light shielding section 22. The trenches 21T and 22T can be formed by dry etching using a hard mask or the like.

Next, as illustrated in 12C, a sidewall 51 is formed to cover a side surface and a bottom surface of each of the trenches 21T and 22T. The sidewall 51 is formed as an insulating film including, for example, silicon nitride (SiN), silicon oxide (SiO₂), or the like.

Next, as illustrated in 12D, the sidewall 51 on the bottom surface is removed while leaving the sidewall 51 on a portion of the side surface of each of the trenches 21T and 22T, and the trenches 21T and 22T are made deeper by a thickness of the horizontal cavity portions 21Z and 22Z to be formed next. Removal of the sidewall 51 on the bottom surface and deepening of the trenches 21T and 22T can be performed by dry etching or the like.

Next, as illustrated in FIG. 12E, the horizontal cavity portions 21Z and 22Z communicating with the bottom portions of the trenches 21T and 22T are formed. The horizontal cavity portions 21Z and 22Z are formed in accordance with the positions of the horizontal light shielding sections 21H and 22H of the first light shielding section 21 and the second light shielding section 22. The horizontal cavity portions 21Z and 22Z can be formed by crystal anisotropic wet etching. Details of a formation method of the horizontal cavity portions 21Z and 22Z by the crystal anisotropic wet etching will be described later.

Next, as illustrated in FIG. 12F, the sidewall 51 is removed, and the trenches 21T and 22T are further extended in the vertical direction. The sidewall 51 can be removed by wet etching or the like. The sidewall 51 may be removed after the trenches 21T and 22T are extended in the vertical direction. In that case, the sidewall 51 can be used as a hard mask for forming the trenches 21T and 22T.

Next, as illustrated in FIG. 12G, the pinning layer 34 is formed in a region around the trenches 21T and 22T and the horizontal cavity portions 21Z and 22Z in the semiconductor substrate 11. The pinning layer 34 can be formed using, for example, a solid phase diffusion method. In the case of using the solid-phase diffusion method, the pinning layer 34 can be formed by a relatively simple method of diffusing P type impurities from the inner surfaces of the trenches 21T and 22T and the horizontal cavity portions 21Z and 22Z. As described above, in the manufacturing method of the imaging element 101 of the present embodiment, the pinning layer 34 can be formed in the front end of line (FEOL) before the wiring layer 31 and the like are formed. Note that, in the following FIGS. 12H to 12N, illustration of the pinning layer 34 is omitted.

Next, as illustrated in FIG. 12H, the insulating films 21B and 22B are formed so as to cover the trenches 21T and 22T and the inner surfaces of the horizontal cavity portions 21Z and 22Z. The insulating films 21B and 22B can be formed by depositing silicon oxide (SiO₂) using an atomic layer deposition method. Furthermore, the insulating films 21B and 22B can also be formed using a chemical vaper deposition method or a thermal oxidation method.

Next, as illustrated in FIG. 12I, the trenches 21T and 22T and the horizontal cavity portions 21Z and 22Z are filled with materials constituting the light shielding material portions 21A and 22A of the first light shielding section 21 and the second light shielding section 22. The filling of the materials constituting the light shielding material portions 21A and 22A can be performed using, for example, a chemical vaper deposition method.

Next, as illustrated in FIG. 12J, the materials constituting the light shielding material portions 21A and 22A and the insulating film 12B on the first surface 11A of the semiconductor substrate 11 are removed. The materials constituting the light shielding material portions 21A and 22A and the insulating film 12B can be removed, for example, by polishing and planarizing the first surface 11A side of the semiconductor substrate 11 by chemical mechanical polishing (CMP).

Next, as illustrated in FIG. 12K, the vertical gate electrode VG and the charge holding section MEM of the transfer transistor TRZ are formed on the first surface 11A side of the semiconductor substrate 11. At this time, the floating diffusion region FD, the insulating layer 33, and the like are also formed. The vertical gate electrode VG can be formed, for example, by forming a trench by dry etching using a hard mask and filling the trench with polysilicon. The charge holding section MEM and the floating diffusion region FD can be formed, for example, by implanting N type ions into the semiconductor substrate 11.

Next, as illustrated in FIG. 12L, the gate electrodes of the transfer transistors TRZ, TRY, TRX, and TRG and the discharge transistor OFG, and the wiring layer 31 are formed on the first surface 11A side of the semiconductor substrate 11. The formation of the wiring layer 31 may include a step of bonding another circuit board.

Next, as illustrated in FIG. 12M, the semiconductor substrate 11 is thinned from the second surface 11B side. Due to the thinning of the semiconductor substrate 11, the vertical light shielding sections 21V and 22V of the first light shielding section 21 and the second light shielding section 22 penetrate the semiconductor substrate 11. Thinning of the semiconductor substrate 11 can be performed by, for example, chemical mechanical polishing (CMP).

Finally, as illustrated in FIG. 12N, the fixed charge film 32, the color filter CF, and the light receiving lens LNS are sequentially formed on the second surface 11B side of the semiconductor substrate 11.

### (Formation of Horizontal Cavity Portions 21Z and 22Z by Crystalline Wet Etching)

Hereinafter, a formation method of the horizontal cavity portions 21Z and 22Z by the crystalline wet etching will be described in detail.

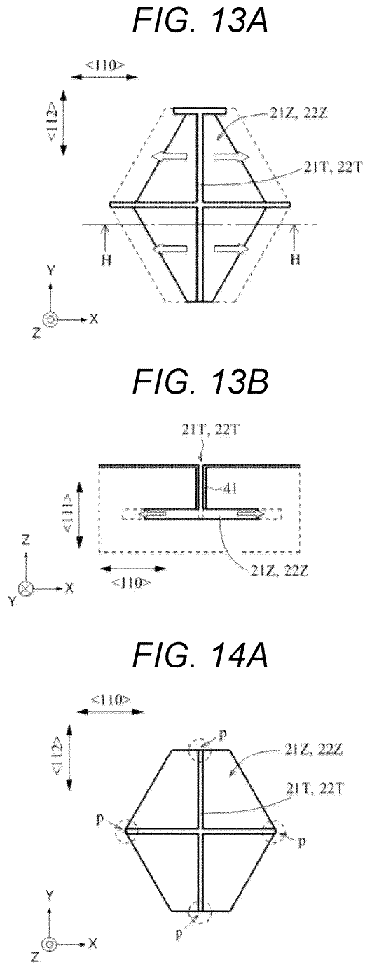

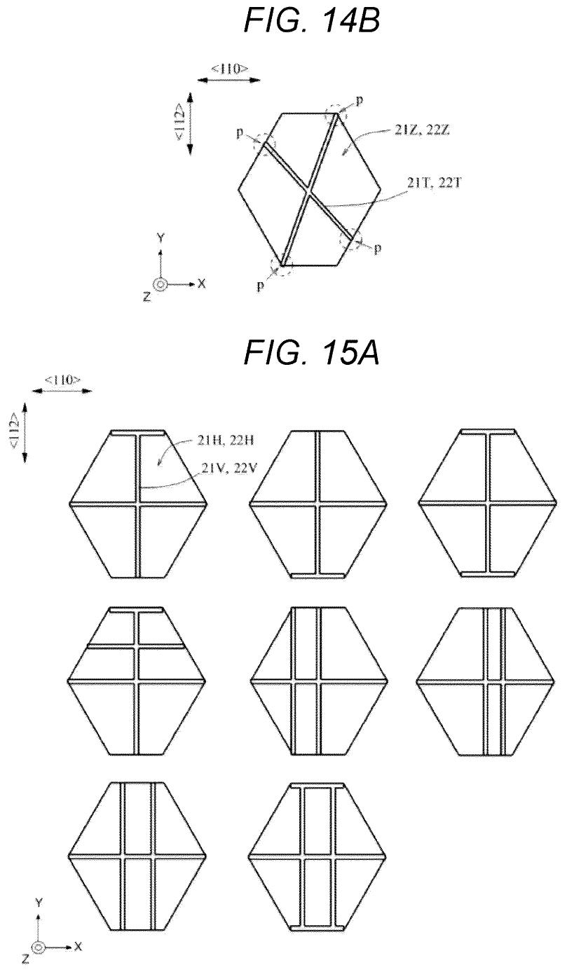

FIG. 13A is a transverse cross-sectional view illustrating a process of forming the horizontal cavity portions 21Z and 22Z by anisotropic wet etching. FIG. 14B is a longitudinal cross-sectional view illustrating a process of forming the horizontal cavity portions 21Z and 22Z by anisotropic wet etching. FIG. 14B illustrates an H-H cross section of FIG. 13A.

In the crystal anisotropic wet etching, chemical liquids having different etching rates according to the plane orientation of the semiconductor substrate 11 are used. Specifically, a chemical solution whose etching rate in the <110> direction is higher than that in the <111> direction or the <112> direction is used. As such a chemical solution, for example, potassium hydroxide (KOH), sodium hydroxide (NaOH), cesium hydroxide (CsOH), hydrazine (N₂H₄), or ammonium hydroxide (NH₄OH) can be used. Furthermore, an organic solution such as an ethylenediamine pyrocatechol aqueous solution (EDP) or tetramethylammonium hydroxide (TMAH) can also be used. A particularly preferable chemical solution is potassium hydroxide (KOH), ammonium hydroxide (NH₄OH), or tetramethylammonium hydroxide (TMAH).

By using such a chemical solution, as illustrated in FIGS. 13A and 13B, etching proceeds in the <110> direction (X direction) from the trenches 21T and 22T extending in the <112> direction (Y direction). On the other hand, since the upper and lower surfaces of the horizontal cavity portions 21Z and 22Z are crystal planes with the plane index {111}, etching hardly proceeds. Furthermore, in the <112> direction (Y direction), etching does not proceed as much as in the <110> direction (X direction). Furthermore, when etching proceeds in the <110> direction (X direction), a crystal plane having the plane index {111} appears. Furthermore, the trenches 21T and 22T extending in the <110> direction (X direction) have a function of promoting the progress of etching.

As illustrated in FIG. 13A, the horizontal cavity portions 21Z and 22Z having a hexagonal shape in plan view are formed by combining the above effects. Furthermore, as described above, since a crystal plane with the plane index {111} appears as etching proceeds, the sidewalls of the horizontal cavity portions 21Z and 22Z correspond to the crystal plane with the plane index {111}. Therefore, the six sides of the hexagon are located on the crystal plane of the plane index {111}, and extend in the <110> direction in plan view. Moreover, the six interior angles of the hexagon are all 1200.

As a result of research, the disclosures of the present disclosure have found a relationship between the arrangement of the trenches 21T and 22T to be described next and the shapes of the horizontal cavity portions 21Z and 22Z formed by the arrangement of the trenches 21T and 22T.

FIGS. 14A and 14B are plan views for explaining the relationship between the arrangement of the trenches 21T and 22T and the shapes of the horizontal cavity portions 21Z and 22Z formed by the arrangement of the trenches 21T and 22T.

As illustrated in FIGS. 14A and 14B, the horizontal cavity portions 21Z and 22Z formed by the above-described crystal anisotropic wet etching have a hexagonal shape in plan view, and the six sides of the hexagonal shape have at least one intersection p with the trenches 21T and 22T, respectively. Note that, in a case where the trenches 21T and 22T intersect at the apex of the hexagon, it is assumed that two sides in contact with the apex have the trenches 21T and 22T and the intersection p.

As illustrated in FIG. 14B, the arrangement of the trenches 21T and 22T is not limited to the combination of the trenches 21T and 22T extending in the <112> direction (Y direction) and the trenches 21T and 22T extending in the <110> direction (X direction). The trenches 21T and 22T may be disposed by a combination of trenches 21T and 22T extending in a direction inclined from the <112> direction (Y direction) and trenches 21T and 22T extending in a direction inclined from the <110> direction (X direction). Even in this case, as illustrated in FIG. 14B, horizontal cavity portions 21Z and 22Z having a hexagonal shape in plan view are formed.

Regarding the formation of the horizontal cavity portions 21Z and 22Z, since autonomous shape control is possible, it is not necessary to use an etching stopper. Therefore, the imaging element 101 manufactured by the above-described manufacturing method has few lattice defects, and as a result, the occurrence of white spots and blinking points is suppressed. Moreover, since the above-described manufacturing method does not require the step of forming the etching stopper, the number of steps is small.

Furthermore, regarding the formation of the horizontal cavity portions 21Z and 22Z by the crystal anisotropic wet etching, there is relatively high tolerance for defective formation of the horizontal cavity portions 21Z and 22Z due to lattice defects of the semiconductor substrate 11. Therefore, the yield can be improved by the above-described manufacturing method.

To summarize the above, the manufacturing method of the imaging element 101 of the present embodiment includes a photoelectric conversion section forming step of forming the photoelectric conversion section 40 in the semiconductor substrate 11 including the first surface 11A and the second surface 11B, a charge holding section forming step of forming the charge holding section MEM in the semiconductor substrate 11, and a light shielding section forming step of forming the first light shielding section 21 and the second light shielding section 22 in the semiconductor substrate 11. The first light shielding section 21 and the second light shielding section 22 respectively include the vertical light shielding sections 21V and 22V that spread in a wall shape in a direction orthogonal to the first surface 11A, and the horizontal light shielding sections 21H and 22H that spread in a plate shape in a direction parallel to the first surface 11A and have a hexagonal shape when viewed from the direction orthogonal to the first surface 11A. The photoelectric conversion section 40 is disposed on the second surface 11B side of the horizontal light shielding section 21H of the first light shielding section 21. The charge holding section MEM is disposed on the first surface 11A side of the horizontal light shielding section 21H of the first light shielding section 21. The horizontal light shielding section 22H of the second light shielding section 22 is disposed closer to the second surface 11B than the horizontal light shielding section 21H of the first light shielding section 21, and is disposed so as to cover a region where the horizontal light shielding section 21H of the first light shielding section 21 is not disposed when viewed from the direction orthogonal to the first surface 11A.

According to such a manufacturing method of the imaging element 101, it is possible to manufacture the imaging element 101 in which the generation of noise caused by crosstalk, dark current, lattice defects, PLS, or the like is suppressed. Furthermore, according to such a manufacturing method of the imaging element 101, the number of steps can be reduced, and the yield can be improved.

### <3. Modifications>

Next, an imaging element 101 according to a modification will be described.

### (Modifications of Configurations of Vertical Light Shielding Section and Horizontal Light Shielding Section)

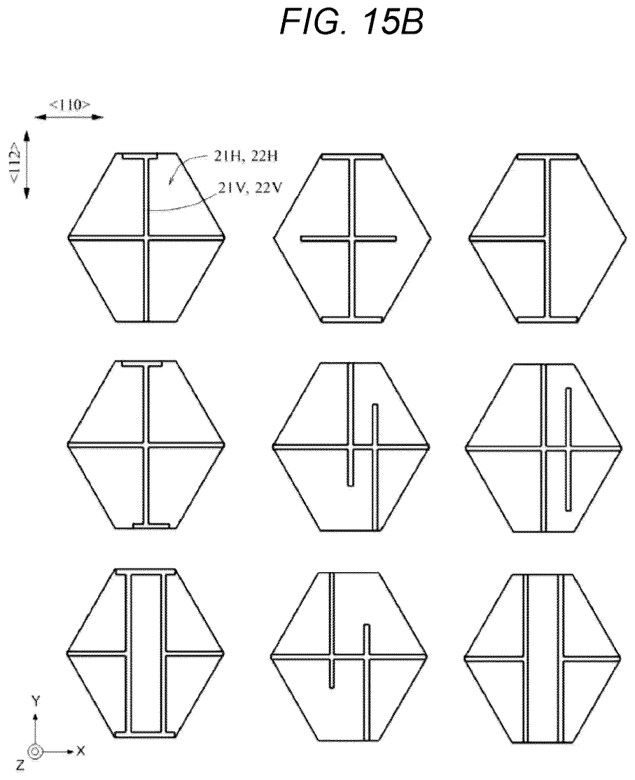

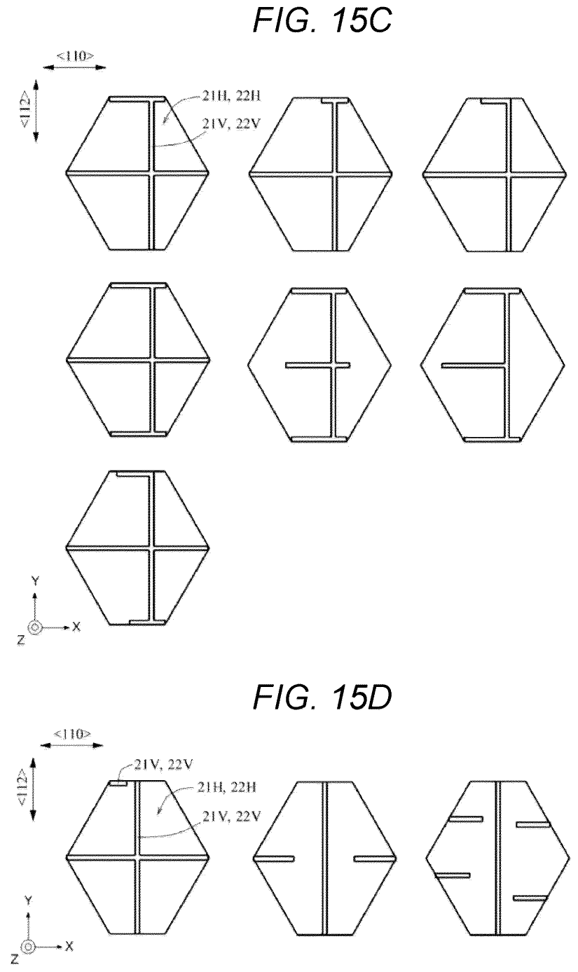

FIGS. 15A to 15F are plan views illustrating modifications of the configurations of the vertical light shielding sections 21V and 22V and the horizontal light shielding sections 21H and 22H. FIGS. 15A to 15F illustrate modes of the vertical light shielding sections 21V and 22V and the horizontal light shielding sections 21H and 22H in plan view.

FIG. 15A illustrates an example in which the numbers of vertical light shielding sections 21V and 22V extending in the <110> direction and the numbers of vertical light shielding sections 21V and 22V extending in the <112> direction are different.

FIG. 15B illustrates an example in which the vertical light shielding sections 21V and 22V of various lengths are disposed.

FIG. 15C illustrates an example in which the vertical light shielding sections 21V and 22V extending in the direction of the crystal orientation <112> are disposed at positions shifted from the centers of the hexagons of the horizontal light shielding sections 21H and 22H.

FIG. 15D illustrates an example in which the vertical light shielding sections 21V and 22V are dispersedly disposed.

FIG. 15E illustrates an example in which the vertical light shielding sections 21V and 22V extend in directions deviated from the <110> direction and the <112> direction.

FIG. 15F illustrates an example in which the hexagonal symmetry of the horizontal light shielding sections 21H and 22H is different.

As described above, the horizontal cavity portions 21Z and 22Z formed in the process of manufacturing the imaging element 101 have a hexagonal shape in plan view, and the six sides of the hexagon each have at least one intersection p with the trenches 21T and 22T. Then, in the manufactured imaging element 101, the horizontal cavity portions 21Z and 22Z and the trenches 21T and 22T are replaced with the horizontal light shielding sections 21H and 22H and the vertical light shielding sections 21V and 22V, respectively.

That is, the relationship between the horizontal light shielding sections 21H and 22H and the vertical light shielding sections 21V and 22V is the same as the relationship between the horizontal cavity portions 21Z and 22Z and the trenches 21T and 22T. Therefore, it can be said that the horizontal light shielding sections 21H and 22H have a hexagonal shape in plan view, and the six sides of the hexagon have at least one intersection p with the vertical light shielding sections 21V and 22V, respectively.

As described above, the horizontal light shielding sections 21H and 22H of the imaging element 101 of the present disclosure may have a hexagonal shape in plan view, and six sides of the hexagon may have at least one intersection p with the vertical light shielding sections 21V and 22V, respectively. Furthermore, the vertical light shielding sections 21V and 22V only need to have a portion extending in the first direction and a portion extending in the second direction non-parallel to the first direction when viewed from the direction orthogonal to the first surface 11A of the semiconductor substrate 11. FIGS. 15A to 15F described above illustrate examples of such a configuration.

### (Modifications of Arrangement of Vertical Light Shielding Section)

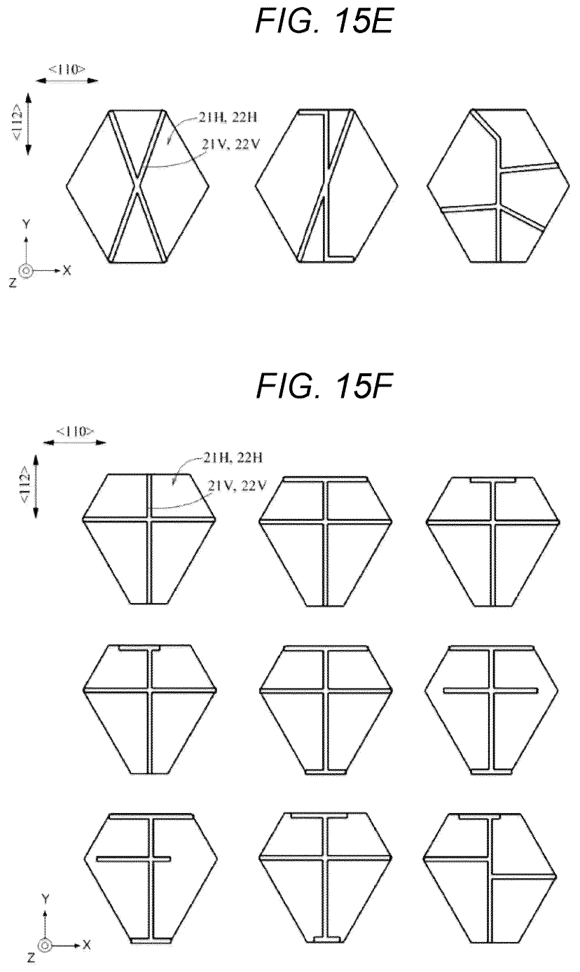

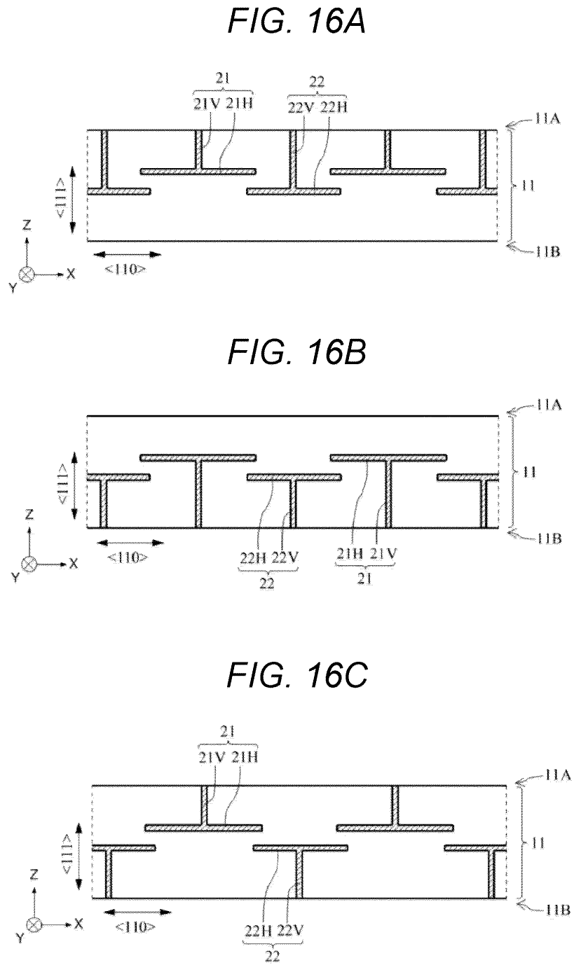

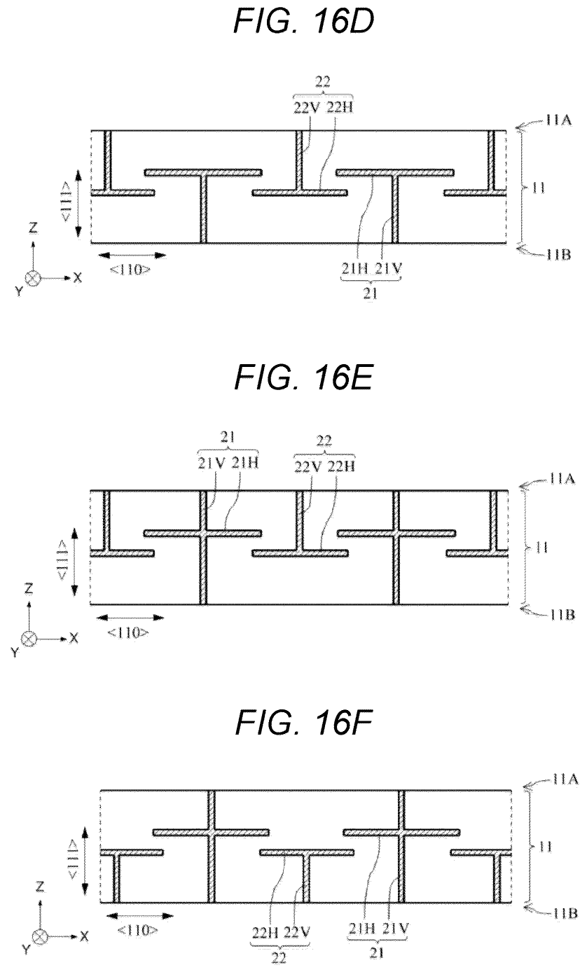

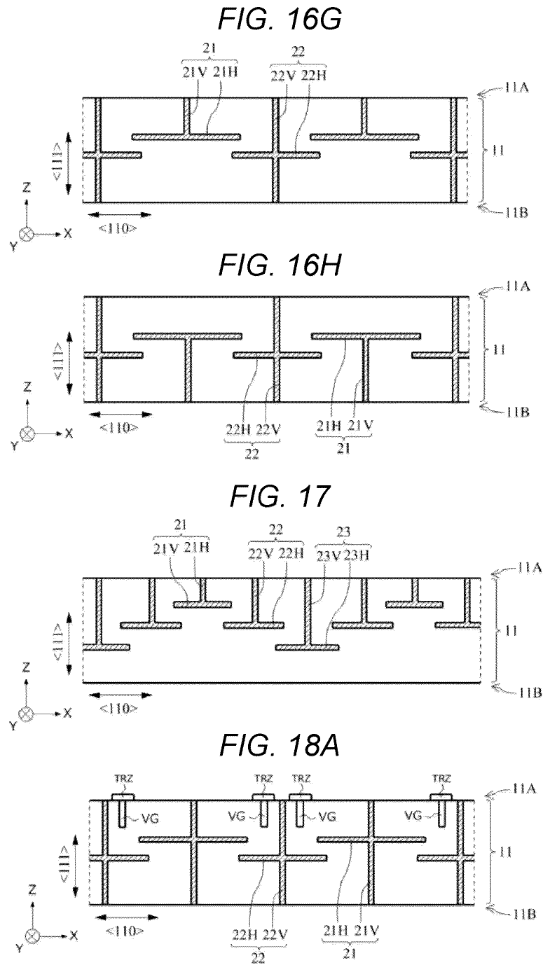

FIGS. 16A to 16H are longitudinal cross-sectional views illustrating modifications of the arrangement of the vertical light shielding sections 21V and 22V.

In the example illustrated in FIG. 16A, the vertical light shielding sections 21V and 22V of the first light shielding section 21 and the second light shielding section 22 are formed only on the first surface 11A side of the semiconductor substrate 11.

In the example illustrated in FIG. 16B, the vertical light shielding sections 21V and 22V of the first light shielding section 21 and the second light shielding section 22 are formed only on the second surface 11B side of the semiconductor substrate 11.

In the example illustrated in FIG. 16C, the vertical light shielding section 21V of the first light shielding section 21 is formed only on the first surface 11A side of the semiconductor substrate 11, and the vertical light shielding section 22V of the second light shielding section 22 is formed only on the second surface 11B side of the semiconductor substrate 11.

In the example illustrated in FIG. 16D, the vertical light shielding section 21V of the first light shielding section 21 is formed only on the second surface 11B side of the semiconductor substrate 11, and the vertical light shielding section 22V of the second light shielding section 22 is formed only on the first surface 11A side of the semiconductor substrate 11.

In the example illustrated in FIG. 16E, the vertical light shielding section 21V of the first light shielding section 21 is formed so as to penetrate the semiconductor substrate 11, and the vertical light shielding section 22V of the second light shielding section 22 is formed only on the first surface 11A side of the semiconductor substrate 11.

In the example illustrated in FIG. 16F, the vertical light shielding section 21V of the first light shielding section 21 is formed so as to penetrate the semiconductor substrate 11, and the vertical light shielding section 22V of the second light shielding section 22 is formed only on the second surface 11B side of the semiconductor substrate 11.

In the example illustrated in FIG. 16G, the vertical light shielding section 21V of the first light shielding section 21 is formed only on the first surface 11A side of the semiconductor substrate 11, and the vertical light shielding section 22V of the second light shielding section 22 is formed so as to penetrate the semiconductor substrate 11.

In the example illustrated in FIG. 16H, the vertical light shielding section 21V of the first light shielding section 21 is formed only on the second surface 11B side of the semiconductor substrate 11, and the vertical light shielding section 22V of the second light shielding section 22 is formed so as to penetrate the semiconductor substrate 11.

As described above, in the imaging element 101 of the present disclosure, both or one of the vertical light shielding sections 21V and 22V of the first light shielding section 21 and the second light shielding section 22 may not penetrate the semiconductor substrate 11. However, in this case, a light shielding section for reducing crosstalk between the sensor pixels 121 is further provided as necessary.

Furthermore, from the viewpoint of ease of forming the first light shielding section 21, the second light shielding section 22, and the pinning layer 34, as illustrated in FIGS. 16A, 16E, and 16G, it is preferable that the vertical light shielding sections 21V and 22V of the first light shielding section 21 and the second light shielding section 22 extend at least from the first surface 11A of the semiconductor substrate 11 to the horizontal light shielding sections 21H and 22H. In this configuration, as described above, the first light shielding section 21, the second light shielding section 22, and the pinning layer 34 can be formed in the FEOL.

Moreover, from the viewpoint of suppressing crosstalk between the adjacent sensor pixels 121, and the like, it is preferable that the first light shielding section 21 and the second light shielding section 22 have vertical light shielding sections 21V and 22V penetrating the semiconductor substrate 11 as in the imaging element 101 of the present embodiment.

### (Modification of the Number of Stages of Light Shielding Section)

FIG. 17 is a longitudinal cross-sectional view illustrating a modification of the number of stages of light shielding sections 21, 22, and 23.

In the example illustrated in FIG. 17, the imaging element 101 includes a third light shielding section 23 in addition to the first light shielding section 21 and the second light shielding section 22. The third light shielding section 23 includes a vertical light shielding section 23V and a horizontal light shielding section 23H. Then, the horizontal light shielding section 23H of the third light shielding section 23 is disposed at a position different from the positions of the horizontal light shielding sections 21H and 22H of the first light shielding section 21 and the second light shielding section 23 in the direction (Z direction) orthogonal to the first surface 11A of the semiconductor substrate 11. As described above, the imaging element 101 of the present disclosure may include three or more types of light shielding sections 21, 22, and 23 having different arrangement positions in the direction (Z direction) orthogonal to the first surface 11A of the semiconductor substrate 11 of the horizontal light shielding sections 21H, 22H, and 23H, respectively.

### (Modification of Arrangement of Horizontal Light Shielding Section of Second Light Shielding Section)

In the imaging element 101 of the above-described present embodiment, in the region corresponding to each sensor pixel 121, the horizontal light shielding section 22H of the second light shielding section 22 is disposed so as to cover all of the region where the horizontal light shielding section 21H of the first light shielding section 21 is not disposed when viewed from the direction orthogonal to the first surface 11A. However, the imaging element 101 of the present disclosure is not limited to such a configuration.

In the imaging element 101 of the present disclosure, in the region corresponding to each sensor pixel 121, the horizontal light shielding section 22H of the second light shielding section 22 may be disposed so as to cover at least a part of the region where the horizontal light shielding section 21H of the first light shielding section 21 is not disposed when viewed from the direction orthogonal to the first surface 11A.

Even if there is a region that does not overlap with any of the horizontal light shielding section 21H of the first light shielding section 21 and the horizontal light shielding section 22H of the second light shielding section 22 in plan view, as in the example illustrated in FIG. 17, in a case where the region is covered with another light shielding structure, a practical problem does not occur. Furthermore, even in a case where the region is hardly affected by incident light, a practical problem does not occur.

However, from the viewpoint of suppressing the generation of noise, it is preferable that the horizontal light shielding section 22H of the second light shielding section 22 be disposed so as to cover at least a part of a region where the horizontal light shielding section 21H of the first light shielding section 21 is not disposed and at least a part of a region where the horizontal light shielding section 21H of the first light shielding section 21 is disposed when viewed from a direction orthogonal to the first surface 11A. Furthermore, it is more preferable that the horizontal light shielding section 22H of the second light shielding section 22 is disposed so as to cover the entire region where the horizontal light shielding section 21H of the first light shielding section 21 is not disposed when viewed from the direction orthogonal to the first surface 11A.

### (Modifications of Vertical Gate Electrode VG of Transfer Transistor TRZ)

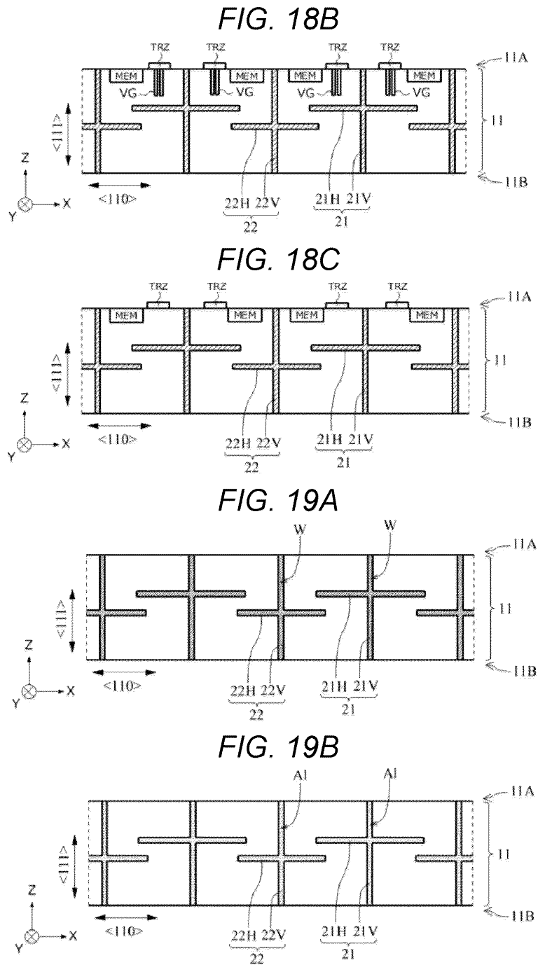

FIGS. 18A to 18C are longitudinal cross-sectional views illustrating modifications of the vertical gate electrode VG of the transfer transistor TRZ.

In the example illustrated in FIG. 18A, the vertical gate electrode VG of the transfer transistor TRZ is disposed in a region not overlapping the horizontal light shielding section 21H of the first light shielding section 21 but overlapping the horizontal light shielding section 22H of the second light shielding section 22 in plan view.

As described above, in the imaging element 101 of the present disclosure, the vertical gate electrode VG of the transfer transistor TRZ is not limited to overlap the horizontal light shielding section 21H of the first light shielding section 21 in plan view. In the imaging element 101 of the present disclosure, the vertical gate electrode VG of the transfer transistor TRZ may be disposed in a region overlapping any of the horizontal light shielding sections 21H and 22H in plan view.

In the example illustrated in FIG. 18B, the transfer transistor TRZ includes two vertical gate electrodes VG. As described above, in the imaging element 101 of the present disclosure, the transfer transistor TRZ may include two or more vertical gate electrodes VG.

In the example illustrated in FIG. 18C, the transfer transistor TRZ does not include a vertical gate electrode. As described above, in the imaging element 101 of the present disclosure, the transfer transistor TRZ may not include the vertical gate electrode. In this case, the transfer transistor TRZ can be configured as, for example, a field effect transistor (FET) having a lateral structure.

### (Modifications of Light Shielding Material Portions)

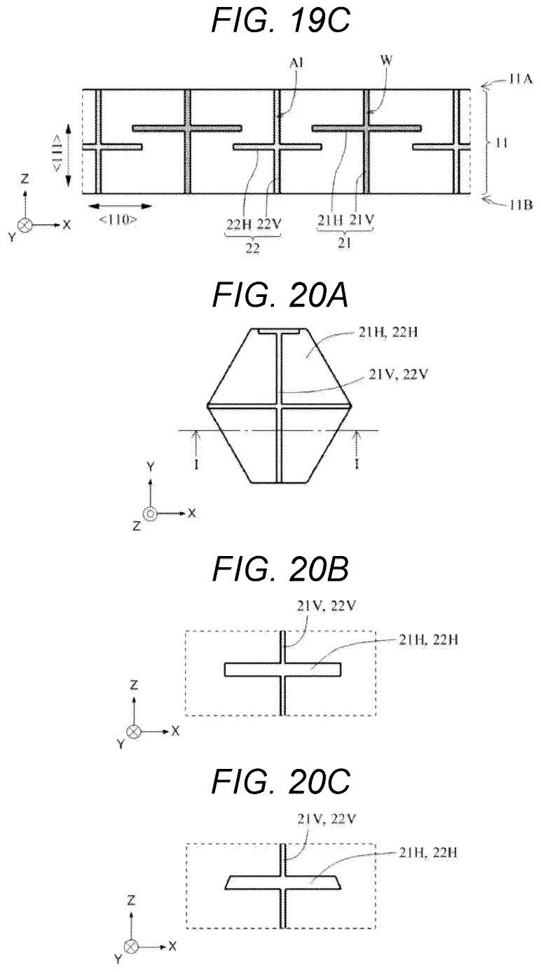

FIGS. 19A to 19C are longitudinal cross-sectional views illustrating modifications of the light shielding material portions 21A and 22A of the first light shielding section 21 and the second light shielding section 22.

In the example illustrated in FIG. 19A, tungsten (W) is used as a material constituting the light shielding material portions 21A and 22A of the first light shielding section 21 and the second light shielding section 22. Tungsten is relatively excellent in light absorbing performance. By using tungsten (W) as a material constituting the light shielding material portions 21A and 22A, PLS can be suppressed to a low level.

In the example illustrated in FIG. 19B, aluminum (Al) is used as a material constituting the light shielding material portions 21A and 22A of the first light shielding section 21 and the second light shielding section 22. Aluminum (Al) is relatively excellent in light reflecting performance. By using aluminum (Al) as a material constituting the light shielding material portions 21A and 22A, the quantum efficiency (Qe) of the imaging element 101 can be improved.

In the example illustrated in FIG. 19C, tungsten (W) is used as a material constituting the light shielding material portions 21A and 22A of the first light shielding section 21, and aluminum (Al) is used as a material constituting the light shielding material portion 22A of the second light shielding section 22. Here, the horizontal light shielding section 21H of the first light shielding section 21 is disposed closer to the first surface 11A (the wiring layer 31 side) than the horizontal light shielding section 22H of the second light shielding section 22. Furthermore, the horizontal light shielding section 22H of the second light shielding section 22 is disposed closer to the second surface 11B (light receiving surface side) than the horizontal light shielding section 21H of the first light shielding section 21.

That is, tungsten (W) having relatively excellent light absorbing performance is used as the material constituting the light shielding material portions 21A and 22A of the first light shielding section 21 in which the horizontal light shielding section 21H is disposed on the first surface 11A side (wiring layer 31 side). Furthermore, aluminum (Al) having relatively excellent light reflecting performance is used as a material constituting the light shielding material portion 22A of the second light shielding section 22 in which the horizontal light shielding section 22H is disposed on the second surface 11B side (light receiving surface side). With this configuration, the quantum efficiency (Qe) of the imaging element 101 can be improved, and PLS can be suppressed to a low level.

### (Modifications of Longitudinal Cross-Sectional Shape of Horizontal Light Shielding Section)

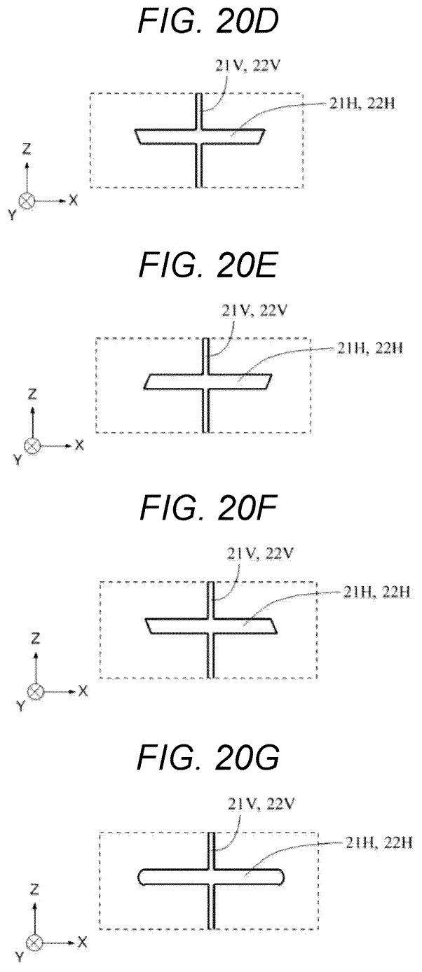

FIG. 20A is a transverse cross-sectional view for explaining a modification of longitudinal cross-sectional shapes of the horizontal light shielding sections 21H and 22H. FIGS. 20B to 20G are longitudinal cross-sectional views illustrating modifications of the longitudinal cross-sectional shapes of the horizontal light shielding sections 21H and 22H. FIGS. 20B to 20G illustrate an I-I cross section of FIG. 20A.

Note that the longitudinal cross-sectional shapes of the horizontal light shielding sections 21H and 22H refer to cross-sectional shapes when the horizontal light shielding sections 21H and 22H are cut by a plane (XZ plane) perpendicular to the first surface 11A of the semiconductor substrate 11 and parallel to the <110> direction.

In the example illustrated in FIG. 20B, the longitudinal cross-sectional shapes of the horizontal light shielding sections 21H and 22H are rectangular. In the example illustrated in FIG. 20C, the longitudinal cross-sectional shapes of the horizontal light shielding sections 21H and 22H are trapezoidal in which the upper base is shorter than the lower base. In the example illustrated in FIG. 20D, the longitudinal cross-sectional shapes of the horizontal light shielding sections 21H and 22H are trapezoidal with the upper base longer than the lower base. In the example illustrated in FIG. 20E, the longitudinal cross-sectional shapes of the horizontal light shielding sections 21H and 22H are square quadrilaterals in which the left and right sides are inclined upward to the right. In the example illustrated in FIG. 20F, the longitudinal cross-sectional shapes of the horizontal light shielding sections 21H and 22H are square quadrilaterals in which the left and right sides are inclined rightward and downward. The difference in vertical cross-sectional shape between the horizontal light shielding sections 21H and 22H is caused by a difference in etching progress at the time of forming the horizontal cavity portions 21Z and 22Z at the time of manufacturing the imaging element 101. Then, the left and right sides of the horizontal light shielding sections 21H and 22H are usually parallel to the crystal plane in which etching is relatively difficult to proceed.

In the example illustrated in FIG. 20G, the longitudinal cross-sectional shape of each of the horizontal light shielding sections 21H and 22H is a rectangle having an arc shape in which the left and right sides bulge outward. Such a shape can be realized by arranging side inner surfaces of the horizontal cavity portions 21Z and 22Z in an arc shape using chemical dry etching (CDE) when the horizontal cavity portions 21Z and 22Z are formed at the time of manufacturing the imaging element 101.

As described above, in the imaging element 101 of the present disclosure, the horizontal light shielding sections 21H and 22H can have various longitudinal cross-sectional shapes.

### (Modifications of Layer Configuration in Semiconductor Substrate 11)

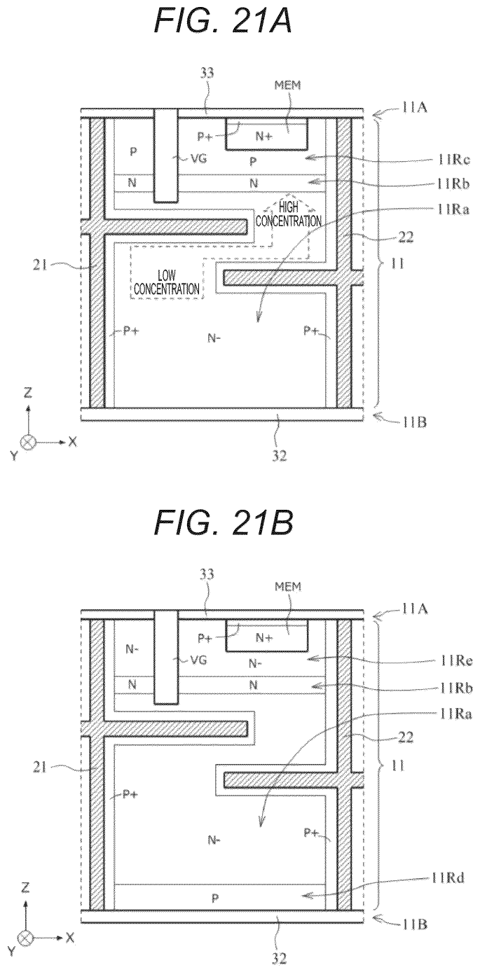

FIGS. 21A and 21B are longitudinal cross-sectional views illustrating modifications of the layer configuration in the semiconductor substrate 11 of the imaging element 101.

In the example illustrated in FIG. 21A, the N type impurity concentration of the N− type semiconductor region 11Ra gradually increases as it goes along a charge transfer path. Here, the charge transfer path refers to a path through which the charge generated in the photoelectric conversion section 40 passes before being transferred to the charge holding section MEM. The N type impurity concentration may be continuously increased or stepwise increased. With this configuration, the charge is smoothly moved along the charge transfer path.

In the example illustrated in FIG. 21B, a P type semiconductor region 11Rd is provided between the N− type semiconductor region 11Ra and the second surface 11B. Then, a photodiode is formed by the P type semiconductor region 11Rd and the N− type semiconductor region 11Ra. A part of the N− type semiconductor region 11Ra of the photodiode serves as the photoelectric conversion section 40. Furthermore, the charge holding section MEM is formed as an N+ semiconductor region formed in an N− semiconductor region Re.

As described above, the layer configuration in the semiconductor substrate is not limited to the configuration of the imaging element 101 of the present embodiment.

### 4. Example of Application to Electronic Equipment

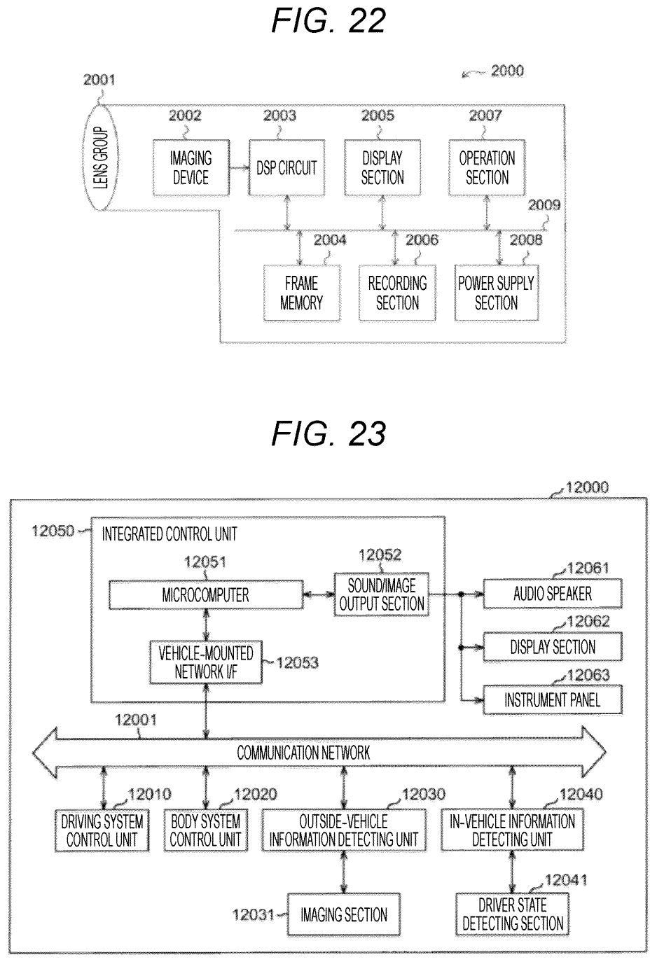

FIG. 22 is a block diagram illustrating a configuration example of a camera 2000 as electronic equipment to which the technology according to the present disclosure is applied.

The camera 2000 includes an optical section 2001 including a lens group and the like, an imaging element (imaging device) 2002 to which the above-described imaging element 101 or the like is applied, and a digital signal processor (DSP) circuit 2003 that is a camera signal processing circuit. Furthermore, the camera 2000 further includes a frame memory 2004, a display section 2005, a recording section 2006, an operation section 2007, and a power supply section 2008. The DSP circuit 2003, the frame memory 2004, the display section 2005, the recording section 2006, the operation section 2007, and the power supply section 2008 are connected to one another through a bus line 2009.

The optical section 2001 captures incident light (image light) from a subject, and forms an image on the imaging surface of the imaging element 2002. The imaging element 2002 converts an amount of the incident light the image of which is formed on the imaging surface by the optical section 2001, into an electric signal on a pixel-by-pixel basis, and outputs the electric signal as a pixel signal.

The display section 2005 includes, for example, a panel type display device such as a liquid crystal panel or an organic EL panel, and displays a moving image or a still image captured by the imaging element 2002. The recording section 2006 records the moving image or the still image captured by the imaging element 2002 in a recording medium such as a hard disk or a semiconductor memory.

The operation section 2007 issues operation commands for various functions of the camera 2000, in response to an operation performed by a user. The power supply section 2008 supplies various power supplies serving as operating power supplies of the DSP circuit 2003, the frame memory 2004, the display section 2005, the recording section 2006, and the operation section 2007, to these supply targets.

As described above, it can be expected to acquire a satisfactory image by using the above-described imaging element 101 and the like as the imaging element 2002.

### 5. Example of Application to Mobile Body

The technology according to the present disclosure can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

FIG. 23 is a block diagram illustrating a schematic configuration example of a vehicle control system 12000 which is an example of a moving body control system to which the technology according to the present disclosure can be applied.

The vehicle control system 12000 includes a plurality of electronic control units connected to each other via a communication network 12001. In the example illustrated in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls an operation of devices related to a drive system of a vehicle in accordance with various programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

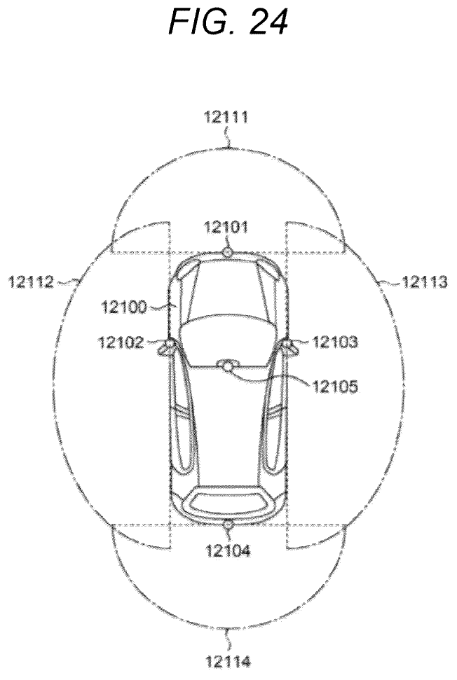

The sound/image output section 12052 transmits an output signal of at least one of a sound and an image to an output device capable of visually or auditorily notifying information to an occupant of the vehicle or the outside of the vehicle. In the example in FIG. 24, an audio speaker 12061, a display section 12062, and an instrument panel 12063 are depicted as the output device. The display section 12062 may, for example, include at least one of an on-board display and a head-up display.

FIG. 24 is a view illustrating an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 24 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the imaging element 101 or the like illustrated in FIG. 1 or the like can be applied to the imaging section 12031. By applying the technology according to the present disclosure to the imaging section 12031, it is possible to expect the vehicle control system to work in an excellent manner.

### 6. Summary

An example of the embodiment of the present disclosure has been described above, but the present disclosure can be implemented in various other forms. For example, various modifications, replacements, omissions, or combinations thereof can be made without departing from the gist of the present disclosure. Such modifications, substitutions, omissions, and the like are also included in the scope of the present disclosure, and are similarly included in the inventions disclosed in the claims and the equivalents thereof.

Furthermore, the effects of the present disclosure described in the present specification are merely an example, and other effects may be achieved.

Note that the present disclosure can have the following configurations.

### [Item 1]

An imaging element including:
a semiconductor substrate including a first surface and a second surface opposed to the first surface; and
a photoelectric conversion section, a charge holding section, a first light shielding section, and a second light shielding section disposed in the semiconductor substrate,
in which each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface,
the photoelectric conversion section is disposed closer to the second surface than the horizontal light shielding section of the first light shielding section,
the charge holding section is disposed closer to the first surface than the horizontal light shielding section of the first light shielding section, and
the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.

### [Item 2]

The imaging element according to item 1, in which
the horizontal light shielding section of the second light shielding section is further disposed to cover at least a part of a region where the horizontal light shielding section of the first light shielding section is disposed.

### [Item 3]

The imaging element according to item 1 or 2, in which
the horizontal light shielding section of the second light shielding section is disposed to cover all of a region where the horizontal light shielding section of the first light shielding section is not disposed when viewed from the direction orthogonal to the first surface.

### [Item 4]

The imaging element according to any one of items 1 to 3, further including
a vertical gate electrode disposed in the semiconductor substrate and extending in the direction orthogonal to the first surface,
in which the vertical gate electrode is disposed closer to the first surface than the horizontal light shielding section of the first light shielding section.

### [Item 5]

The imaging element according to any one of items 1 to 4, in which
the semiconductor substrate is a single-crystal silicon substrate in which the first plane is a crystal plane with a plane index {111},
the vertical light shielding section includes a portion extending in a first direction and a portion extending in a second direction non-parallel to the first direction when viewed from the direction orthogonal to the first plane, and
all of six sides of the hexagonal shape of the horizontal light shielding section have at least one intersection with the vertical light shielding section.

### [Item 6]

The imaging element according to item 5, in which
the first direction is a crystal direction with a direction index <112>, and
the second direction is a crystal direction with a direction index <110>.

### [Item 7]

The imaging element according to any one of items 1 to 6, further including
a pinning layer disposed in a region around the first light shielding section and the second light shielding section in the semiconductor substrate and formed as a P type semiconductor region.

### [Item 8]

The imaging element according to any one of items 1 to 7, in which
the vertical light shielding section of each of the first light shielding section and the second light shielding section extends from at least the first surface to the horizontal light shielding section.

### [Item 9]

The imaging element according to any one of items 1 to 8, in which
the vertical light shielding section of each of the first light shielding section and the second light shielding section penetrates the semiconductor substrate.

### [Item 10]

A manufacturing method of an imaging element, the manufacturing method including:
a photoelectric conversion section forming step of forming a photoelectric conversion section in a semiconductor substrate including a first surface and a second surface opposite to the first surface;
a charge holding section forming step of forming a charge holding section in the semiconductor substrate; and
a light shielding section forming step of forming a first light shielding section and a second light shielding section in the semiconductor substrate,
in which each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface,
the photoelectric conversion section is disposed closer to the second surface than the horizontal light shielding section of the first light shielding section,
the charge holding section is disposed closer to the first surface than the horizontal light shielding section of the first light shielding section, and
the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.

### [Item 11]

A manufacturing method of an imaging element according to item 10, in which
a single-crystal silicon substrate in which the first surface is a crystal plane with a plane index {111} is used as the semiconductor substrate, and
the light shielding section forming step includes:
a trench forming step of forming a trench that spreads in a wall shape from the first surface in a direction orthogonal to the first surface; and
a horizontal cavity portion forming step of forming a horizontal cavity portion that spreads in a plate shape in a direction parallel to the first surface by crystal anisotropic wet etching from the trench formed in the trench forming step and has a hexagonal shape when viewed from the direction orthogonal to the first surface.

### [Item 12]

The manufacturing method of an imaging element according to item 11, in which
the light shielding section forming step includes a step of forming a pinning layer in a region around the trench and the horizontal cavity portion in the semiconductor substrate by diffusing P type impurities from the trench formed in the trench forming step and an inner surface of the horizontal cavity portion formed in the horizontal cavity portion forming step.

### [Item 13]

Electronic equipment including the imaging element according to any one of items (1) to (9).

REFERENCE SIGNS LIST

| | |
|---|---|
| 101 | Imaging element |
| 111 | Pixel array section |
| 112 | Vertical drive section |
| 113 | Ramp wave module |
| 114 | Column signal processing section |
| 115 | Clock module |
| 116 | Data storage section |
| 117 | Horizontal drive section |
| 118 | System control section |
| 119 | Signal processing section |
| 121 | Sensor pixel |
| 122 | Pixel drive line |
| 123 | Vertical signal line |
| 11 | Semiconductor substrate |
| 11A | First surface |
| 11B | Second surface |
| 11Ra | N- type semiconductor region |
| 11Rb | N type semiconductor region |
| 11Rc | P type semiconductor region |
| 21 | First light shielding section |
| 21A | Light shielding material portion |
| 21B | Insulating film |
| 21H | Horizontal light shielding section |
| 21V | Vertical light shielding section |
| 21T | Trench |
| 21Z | Horizontal cavity portion |
| 22 | Second light shielding section |
| 22A | Light shielding material portion |
| 22B | Insulating film |
| 22H | Horizontal light shielding section |
| 22V | Vertical light shielding section |
| 22T | Trench |
| 22Z | Horizontal cavity portion |
| 31 | Wiring layer |
| 32 | Fixed charge film |
| 33 | Insulating layer |
| 34 | Pinning layer |
| 40 | Photoelectric conversion section |
| 51 | Sidewall |
| PD | Photodiode |
| TRX | Transfer transistor |
| TRY | Transfer transistor |
| TRZ | Transfer transistor |
| VG | Vertical gate electrode |
| TRG | Transfer transistor |
| MEM | Charge holding section |
| FD | Floating diffusion region |
| OFG | Discharge transistor |
| RST | Reset transistor |
| AMP | Amplification transistor |
| SEL | Selection transistor |
| VDD | Power supply line |
| VSL | Vertical signal line |
| CF | Color filter |
| LNS | Light receiving lens |

1. An imaging element comprising:
a semiconductor substrate including a first surface and a second surface opposed to the first surface; and
a photoelectric conversion section, a charge holding section, a first light shielding section, and a second light shielding section disposed in the semiconductor substrate,
wherein each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface,
the photoelectric conversion section is disposed closer to the second surface than the horizontal light shielding section of the first light shielding section,
the charge holding section is disposed closer to the first surface than the horizontal light shielding section of the first light shielding section, and
the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.

2. The imaging element according to claim 1, wherein
the horizontal light shielding section of the second light shielding section is further disposed to cover at least a part of a region where the horizontal light shielding section of the first light shielding section is disposed.

3. The imaging element according to claim 1, wherein
the horizontal light shielding section of the second light shielding section is disposed to cover all of a region where the horizontal light shielding section of the first light shielding section is not disposed when viewed from the direction orthogonal to the first surface.

4. The imaging element according to claim 1, further comprising
a vertical gate electrode disposed in the semiconductor substrate and extending in the direction orthogonal to the first surface,
wherein the vertical gate electrode is disposed closer to the first surface than the horizontal light shielding section of the first light shielding section.

5. The imaging element according to claim 1, wherein
the semiconductor substrate includes a single-crystal silicon substrate in which the first plane includes a crystal plane with a plane index {111},
the vertical light shielding section includes a portion extending in a first direction and a portion extending in a second direction non-parallel to the first direction when viewed from the direction orthogonal to the first plane, and
all of six sides of the hexagonal shape of the horizontal light shielding section have at least one intersection with the vertical light shielding section.

6. The imaging element according to claim 5, wherein
the first direction is a crystal direction with a direction index <112>, and
the second direction is a crystal direction with a direction index <110>.

7. The imaging element according to claim 1, further comprising
a pinning layer disposed in a region around the first light shielding section and the second light shielding section in the semiconductor substrate and formed as a P type semiconductor region.

8. The imaging element according to claim 1, wherein
the vertical light shielding section of each of the first light shielding section and the second light shielding section extends from at least the first surface to the horizontal light shielding section.

9. The imaging element according to claim 1, wherein
the vertical light shielding section of each of the first light shielding section and the second light shielding section penetrates the semiconductor substrate.

10. A manufacturing method of an imaging element, the manufacturing method comprising:
a photoelectric conversion section forming step of forming a photoelectric conversion section in a semiconductor substrate including a first surface and a second surface opposite to the first surface;
a charge holding section forming step of forming a charge holding section in the semiconductor substrate; and
a light shielding section forming step of forming a first light shielding section and a second light shielding section in the semiconductor substrate,
wherein each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface,
the photoelectric conversion section is disposed closer to the second surface than the horizontal light shielding section of the first light shielding section,
the charge holding section is disposed closer to the first surface than the horizontal light shielding section of the first light shielding section, and
the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.

11. The manufacturing method of an imaging element according to claim 10, wherein
a single-crystal silicon substrate in which the first surface is a crystal plane with a plane index {111} is used as the semiconductor substrate, and
the light shielding section forming step includes:
a trench forming step of forming a trench that spreads in a wall shape from the first surface in a direction orthogonal to the first surface; and
a horizontal cavity portion forming step of forming a horizontal cavity portion that spreads in a plate shape in a direction parallel to the first surface by crystal anisotropic wet etching from the trench formed in the trench forming step and has a hexagonal shape when viewed from the direction orthogonal to the first surface.

12. The manufacturing method of an imaging element according to claim 11, wherein
the light shielding section forming step includes a step of forming a pinning layer in a region around the trench and the horizontal cavity portion in the semiconductor substrate by diffusing P type impurities from the trench formed in the trench forming step and an inner surface of the horizontal cavity portion formed in the horizontal cavity portion forming step.

13. Electronic equipment comprising an imaging element, wherein
the imaging element includes:
a semiconductor substrate including a first surface and a second surface opposed to the first surface; and
a photoelectric conversion section, a charge holding section, a first light shielding section, and a second light shielding section disposed in the semiconductor substrate,
each of the first light shielding section and the second light shielding section includes a vertical light shielding section that spreads in a wall shape in a direction orthogonal to the first surface, and a horizontal light shielding section that spreads in a plate shape in a direction parallel to the first surface and has a hexagonal shape when viewed from the direction orthogonal to the first surface,
the photoelectric conversion section is disposed closer to the second surface than the horizontal light shielding section of the first light shielding section,
the charge holding section is disposed closer to the first surface than the horizontal light shielding section of the first light shielding section, and
the horizontal light shielding section of the second light shielding section is disposed closer to the second surface than the horizontal light shielding section of the first light shielding section, and is disposed to cover at least a part of a region where the horizontal light shielding section of the first light shielding section is not disposed when viewed from the direction orthogonal to the first surface.
